(19) United States
(12) Patent Application Publication
(10) Pub. No.: US 2013/0286714 A1
(43) Pub. Date: Oct. 31, 2013

(54) DATA WRITE METHOD FOR WRITING DATA TO NONVOLATILE MEMORY ELEMENT, AND NONVOLATILE MEMORY DEVICE

(71) Applicant: Panasonic Corporation, Osaka (JP)

(72) Inventors: Takeshi Takagi, Kyoto (JP); Zhiqiang Wei, Osaka (JP)

(73) Assignee: Panasonic Corporation, Osaka (JP)

(21) Appl. No.: 13/989,282

(22) PCT Filed: Sep. 25, 2012
(86) PCT No.: PCT/JP2012/006093

§ 371 Date: May 23, 2013

(30) Foreign Application Priority Data
Sep. 28, 2011 (JP) 2011-212088

(51) Int. Cl. G11C 13/00

(52) U.S. Cl. CPC G11C 13/0069
USPC 365/148

(57) ABSTRACT

Provided is a data write method for writing data to a nonvolatile memory element, the data write method including: a first application step of applying a first voltage pulse for changing a resistance state of the nonvolatile memory element from a first state to a second state; a second application step of applying a second voltage pulse which has a same polarity as the first voltage pulse and a voltage value of which has a smaller absolute value than the first voltage pulse; a determination step of determining whether the resistance state of the nonvolatile memory element is the second state; and a third application step of applying a third voltage pulse for changing the resistance state of the nonvolatile memory element from the first state to the second state when it is determined that the resistance state of the nonvolatile memory element is not the second state.

### TECHNICAL FIELD

The present invention relates to a data write method for writing data to a variable resistance nonvolatile memory element a resistance value of which changes according to an electrical signal provided thereto, and a nonvolatile memory device implementing the method.

### BACKGROUND ART

In recent years, with advance in digital technology, electronic devices such as mobile information devices and information home appliances have been developed to provide higher functionality. Therefore, there is increasing demands for nonvolatile memory devices incorporated in these devices to have a large capacity, reduced write power, shorter write/read time, and a long lifetime. In response to such demands, miniaturization of existing flash memory using a floating gate is said to be limited. Therefore, there arises a problem that it is difficult to increase the capacity of the nonvolatile memory devices. Thus, there is on-going research and development of nonvolatile memory devices including variable resistance nonvolatile memory elements the resistance values of which reversely change according to electrical signals.

The nonvolatile memory element as described above has a fairly simple structure in which a variable resistance layer is sandwiched between a bottom electrode and a top electrode. Then, the resistance state of the variable resistance layer changes to a high resistance state or a low resistance state by only giving between the top and bottom electrodes a predetermined electrical pulse of a voltage equal to or greater than a certain threshold value. By associating these different resistance states and data with each other, information is recorded. As described above, because of the simplicity in structure and operation, further miniaturization and cost reduction of the variable resistance nonvolatile memory element are expected to be possible. Moreover, the resistance change between the high resistance and the low resistance can occur on the order of 100 nanoseconds (ns) or less, and thus the variable resistance nonvolatile memory element draws attention also from the stand point of high-speed operation.

Such variable resistance nonvolatile memory elements are broadly categorized in two types, based on a material (a variable resistance material) used as the variable resistance layer. One type is a variable resistance nonvolatile memory element, disclosed in PTL 1 or the like, that uses a perovskite material (such as Pr₍₁₋ₓ₎CaₓMnO₃ (PCMO), LaSrMnO₃ (LSMO), GdBaCoₓO_{y} (GBCO)) as the variable resistance material. The other type is a variable resistance nonvolatile memory element that uses a binary transition metal oxide as the variable resistance material. The binary transition metal oxide has a fairly simple composition and structure as compared to the above-described perovskite material. Thus, compositional control and deposition upon manufacturing are easy. In addition, the binary transition metal oxide has an advantage of having relatively good conformity with semiconductor manufacturing processes, and thus, recently, numerous studies are made thereon.

While the physical mechanism of the resistance change is still poorly understood, the recent results of studies show that the resistance change is believed to occur because a conductive filament is formed in a binary transition metal oxide and the density of oxygen deficiency in the filament changes due to oxidation-reduction (for example, see PTL 2 and NPL 1).

### CITATION LIST

### Patent Literature

[PTL 1] U.S. Pat. No. 6,473,332
[PTL 2] Japanese Unexamined Patent Application Publication No. 2008-306157

### Non Patent Literature

[NPL 1] R. Waser et al., Advanced Materials, NO21, 2009, pp. 2632-2663

### SUMMARY OF INVENTION

### Technical Problem

The nonvolatile memory element by definition has characteristics in which after information is electrically stored therein, the information is retained without volatilizing (lost, degradation, change) even if the power is turned off. In general, however, it is inevitable for any nonvolatile memory element that the stored information ends up being changed within a finite time period.

The variable resistance nonvolatile memory element is no exception and has characteristics that once-stored information ends up being changed gradually over time. In this case, the change made to the information is observed to be as change of a set resistance value over time. In general, the phenomenon is known in which the stored information degrades by the resistance state gradually changing from the high resistance state to the low resistance state or from the low resistance state to the high resistance state after some considerable time (for example, 100 hours or more) is elapsed.

The inventors have found new resistance value changing phenomenon in which the resistance value increases and decreases in a short time, in addition to such degradation (degradation in retention characteristics) of information caused by the resistance value slowly changing over a relatively long time. In the phenomenon, the set resistance value randomly changes in a short time which is within a few minutes after an electrical pulse is applied to the nonvolatile memory element, which is observed in a nonvolatile memory element where a tantalum (Ta) oxide is employed as the variable resistance material. The similar physical is also reported in a variable resistance nonvolatile memory element where a nickel (Ni) oxide is employed as the variable resistance material (Non Patent Literature 2: Daniele lelmini, et al., Appl. Phys. Lett., Vol. 96, 2010, pp. 53503), and conceived to commonly occur in variable resistance nonvolatile memory elements.

However, methods have not previously been proposed which are effective in reducing variations (i.e., fluctuation) in resistance value which varies in the short time. It should be noted that herein, the resistance variation phenomenon in such a short time will be referred to as “fluctuation in resistance value” or simply as “fluctuation,” as distinguished from the above-described resistance variation phenomenon in a long time.

The present invention is made in view of the above problems and based on the knowledge (described below) newly found by the inventors with respect to the above-described fluctuation in resistance value. A primary object of the present invention is to provide a data write method for writing data to the nonvolatile memory element which can reduce the effects of the fluctuations described above and a nonvolatile memory device which implements the method.

### Solution to Problem

To solve the above-mentioned problems, a data write method for writing data to the nonvolatile memory element according to one aspect of the present invention is a data write method for writing data to a nonvolatile memory element including a first electrode, a second electrode, and a variable resistance layer comprising a metal oxide and interposed between the first electrode and the second electrode, the data write method including: a first application step of applying, between the first electrode and the second electrode, a first voltage pulse for changing a resistance state of the nonvolatile memory element from a first state to a second state; a second application step of applying, after the first application step, between the first electrode and the second electrode, a second voltage pulse which has a same polarity as the first voltage pulse and a voltage an absolute value of which is smaller than an absolute value of a voltage of the first voltage pulse; a determination step of determining, after the second application step, whether the resistance state of the nonvolatile memory element is the second state; and a third application step of applying, between the first electrode and the second electrode, a third voltage pulse for changing the resistance state of the nonvolatile memory element from the first state to the second state when it is determined in the determination step that the resistance state of the nonvolatile memory element is not the second state.

Moreover, to solve the above-mentioned problems, a nonvolatile memory device according to one aspect of the present invention is a nonvolatile memory device including: a nonvolatile memory element including a first electrode, a second electrode, and a variable resistance layer comprising a metal oxide and interposed between the first electrode and the second electrode; a write unit configured to apply, between the first electrode and the second electrode, a first voltage pulse for changing a resistance state of the nonvolatile memory element from a first state to a second state, and subsequently, apply, between the first electrode and the second electrode, a second voltage pulse which has a same polarity as the first voltage pulse and a voltage an absolute value of which is smaller than an absolute value of a voltage of the first voltage pulse; a determination unit configured to determine, after application of the second voltage pulse, whether the resistance state of the nonvolatile memory element is the second state; and a rewrite unit configured to apply, between the first electrode and the second electrode, a third voltage pulse for changing the resistance state of the nonvolatile memory element from the first state to the second state when the determination unit determines that the resistance state of the nonvolatile memory element is not the second state.

### Advantageous Effects of Invention

According to the data write method for writing data to the nonvolatile memory element and the nonvolatile memory device according to the present invention, the effects of the fluctuation can be reduced and the data retention characteristics can be improved.

### BRIEF DESCRIPTION OF DRAWINGS

FIG. 1A is a sectional view of the configuration of a nonvolatile memory element according to the embodiment 1 of the present invention.

FIG. 1B is a sectional view of a local region formed in a second metal oxide layer of the nonvolatile memory element.

FIG. 2 is a diagram illustrating the formation of a filament in a variable resistance layer.

FIG. 3 is a circuit structure diagram when a voltage pulse is applied to the nonvolatile memory element according to the embodiment 1 of the present invention.

FIG. 4 is a diagram showing variations in resistance value of the nonvolatile memory element according to the embodiment 1 of the present invention.

FIG. 5 is plot of the maximum values and minimum values of the variations in resistance value of the nonvolatile memory element according to the embodiment 1 of the present invention in a high resistance state.

FIG. 6 is a diagram showing the relationship between a current value and normal distribution of the current value when the nonvolatile memory element according to the embodiment 1 of the present invention is in the high resistance state.

FIG. 7A a flowchart illustrating the procedure of data write process of the nonvolatile memory element according to the embodiment 1 of the present invention.

FIG. 7B is a flowchart corresponding to the summarization of the procedure illustrated in the flowchart of FIG. 7A.

FIG. 8 is a diagram illustrating the application of the voltage pulse in a write process and a verify read process.

FIG. 9 is a diagram showing the relationship between an effective voltage and the current value when a positive polarity voltage pulse is applied to the nonvolatile memory element alone in the high resistance state.

FIG. 10 is a diagram showing the relationship between an effective voltage and the resistance value when a positive polarity voltage pulse is applied to the nonvolatile memory element alone in the high resistance state.

FIG. 11 is a diagram showing the relationship between an effective voltage and the current value when a negative polarity voltage pulse is applied to the nonvolatile memory element alone in a low resistance state.

FIG. 12 is a block diagram of a configuration example of a nonvolatile memory device according to an embodiment 2 of the present invention.

FIG. 13 is a block diagram of a configuration example of a nonvolatile memory device according to an embodiment 3 of the present invention.

FIG. 14 is a diagram showing variations in resistance value of a conventional nonvolatile memory element.

### DESCRIPTION OF EMBODIMENTS

First, before describing embodiments according to the present invention, experiments actually performed with respect to the fluctuation in resistance value in the variable resistance nonvolatile memory element will be described. It should be noted that while the following description is intended as an aid in understanding the present invention, the following various experimental conditions and the like are not meant to limit the present invention.

Hereinafter, the inventors fabricated a nonvolatile memory element using, as a variable resistance material, Ta oxide which is of oxygen-deficient in stoichiometric composition, and operated the nonvolatile memory element by applying an electrical pulse thereto to examine, in detail, how the set resistance value changes over time. The variable resistance nonvolatile memory element has bipolar switching characteristics in which the resistance state of the nonvolatile memory element changes to the high resistance state when a positive voltage relative to the bottom electrode is applied to the top electrode, and the resistance state changes to the low resistance state when a negative voltage relative to the bottom electrode is applied in the same manner.

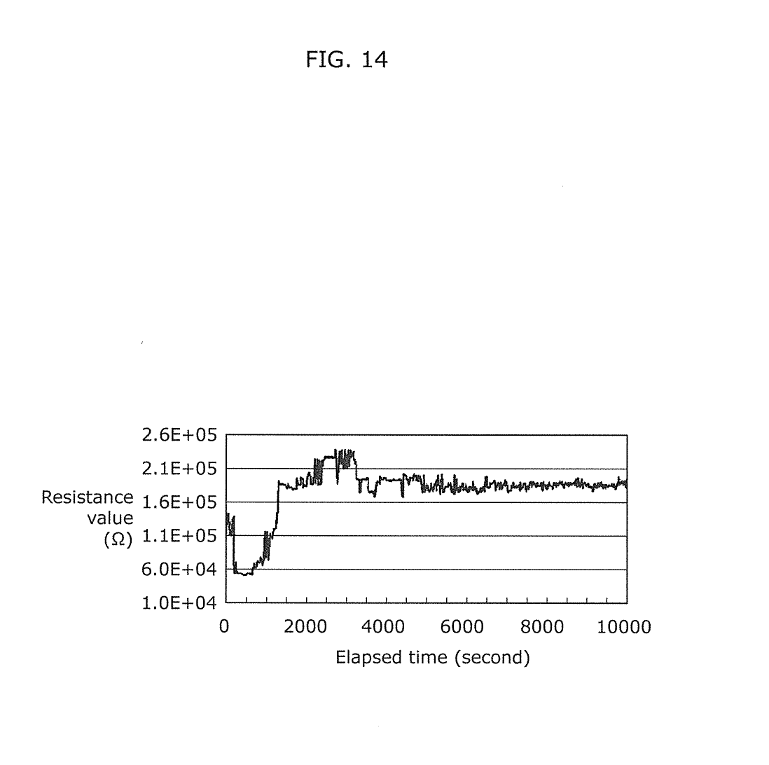

The measurement result is shown in FIG. 14. Herein, the nonvolatile memory element was operated by alternately applying, for 100 times in total, an electrical pulse of +2.5 V for 100 ns and an electrical pulse of −2.0 V for 100 ns to the fabricated nonvolatile memory element in a state being connected to a load resistance of 6.4 kΩ in series. Then, the electrical pulse of +2.5 V for 100 ns was last applied to the nonvolatile memory element, to set the resistance state of the nonvolatile memory element to the high resistance state (about 120 kΩ). In this state, the nonvolatile memory element was kept at room temperature and examined as to how the resistance value changes over time (i.e., fluctuation).

Referring to FIG. 14, it can be seen that the resistance value of the nonvolatile memory element repeatedly and drastically increases and decreases while the nonvolatile memory element is kept at room temperature and no voltage sufficiently large to cause resistance change is applied thereto. Specifically, the resistance value largely collapse down to about 50 kΩ 200 seconds after the last application of the electrical pulse, and increases 1000 seconds thereafter, reaching 200 kΩ.

As described above, since the initially set resistance value (about 120 kΩ) largely increases and decreases in a short time, data read error may occur. Hereinafter, the nonvolatile memory element where the set resistance value the measurement result of which is indicated in FIG. 14 is 120 kΩ will be described by way of example. Here, assuming that 60 kΩ which is half the set resistance value is a threshold value (data decision point, reference level), the nonvolatile memory element which has the resistance value of 60 kΩ or greater is defined to be in the high resistance state, and the nonvolatile memory element which has the resistance value of less than 60 kΩ is defined to be in the low resistance state. In this case, when the resistance value of the nonvolatile memory element is read about 1000 seconds after the resistance value is set (i.e., the resistance value of the nonvolatile memory element is set to 120 kΩ), the resistance value is 50 kΩ. Thus, it is determined that the nonvolatile memory element is in the low resistance state. On the other hand, when the resistance value of the nonvolatile memory element is read 2000 seconds after the resistance value is set, the resistance value exceeds 200 kΩ. Thus, it is determined that the nonvolatile memory element is in the high resistance state. As described above, depending on a time at which data is read, a situation is created where data of the same nonvolatile memory element may be “1” or may be “0.”

Thus, having repeated experiments and considerations, the inventors have devised a data write method which can reduce such effects of the fluctuation and improve the data retention characteristics in the variable resistance nonvolatile memory element.

One aspect of the data write method is a data write method for writing data to a nonvolatile memory element including a first electrode, a second electrode, and a variable resistance layer comprising a metal oxide and interposed between the first electrode and the second electrode, the data write method including: a first application step of applying, between the first electrode and the second electrode, a first voltage pulse for changing a resistance state of the nonvolatile memory element from a first state to a second state; a second application step of applying, after the first application step, between the first electrode and the second electrode, a second voltage pulse which has a same polarity as the first voltage pulse and a voltage an absolute value of which is smaller than an absolute value of a voltage of the first voltage pulse; a determination step of determining, after the second application step, whether the resistance state of the nonvolatile memory element is the second state; and a third application step of applying, between the first electrode and the second electrode, a third voltage pulse for changing the resistance state of the nonvolatile memory element from the first state to the second state when it is determined in the determination step that the resistance state of the nonvolatile memory element is not the second state.

According to this, after the writing is performed to change the resistance state of the nonvolatile memory element from the first state to the second state, the writing for the fluctuation determination is performed, and if it is determined that the resistance value of the nonvolatile memory element is likely to fluctuate, the rewriting is performed. Thus, the effects of the fluctuations are reduced and the data retention characteristics improve.

Here, the first state may be a low resistance state, and the second state may be a high resistance state in which a resistance value of the nonvolatile memory element is higher than the resistance value in the low resistance state. In other words, the data write method according to the present invention may be applied to high resistance writing.

Herein, preferably, the absolute value of the voltage of the second voltage pulse is greater than or equal to a minimum voltage at which a current starts flowing through the nonvolatile memory element upon application of a voltage between the first electrode and the second electrode when the resistance state of the nonvolatile memory element is the high resistance state, and less than or equal to a maximum voltage at which breakdown is not caused in the nonvolatile memory element upon application of a voltage between the first electrode and the second electrode when the resistance state of the nonvolatile memory element is the high resistance state. For example, preferably, the minimum voltage is 0.6 V, and the maximum voltage is 1.3 V.

Likewise, the first state may be a high resistance state, and the second state may be a low resistance state in which a resistance value of the nonvolatile memory element is lower than the resistance value in the high resistance state. In other words, the data write method according to the present invention may be applied to low resistance writing.

Herein, preferably, the absolute value of the voltage of the second voltage pulse is greater than or equal to a minimum voltage at which a current starts flowing through the nonvolatile memory element upon application of a voltage between the first electrode and the second electrode when the resistance state of the nonvolatile memory element is the low resistance state, and less than or equal to a maximum voltage at which progression of resistance change of the nonvolatile memory element to the low resistance state is not caused upon application of a voltage between the first electrode and the second electrode when the resistance state of the nonvolatile memory element is the low resistance state. For example, preferably, the minimum voltage is 0.05 V, and the maximum voltage is 0.75 V.

Moreover, the third voltage pulse may have a same voltage as the first voltage pulse, or the third voltage pulse may have a voltage an absolute value of which is greater than the absolute value of the voltage of the first voltage pulse.

Moreover, as characteristics of the nonvolatile memory element, the metal oxide may be a tantalum oxide, and the resistance state of the nonvolatile memory element may transition from the first state to the second state or from the second state to the first state, according to a polarity of a voltage pulse applied between the first electrode and the second electrode, the nonvolatile memory element being a bipolar memory element. Furthermore, the variable resistance layer may have a stacked structure including a first metal oxide layer comprising a first metal oxide, and a second metal oxide layer comprising a second metal oxide, and an oxygen deficiency in the first metal oxide layer may be greater than an oxygen deficiency in the second metal oxide layer. The second metal oxide layer may have a filament which is a current path through which a current having a locally high current density flows in the second metal oxide layer and the second metal oxide layer may have a region having a locally high oxygen vacancy concentration in the second metal oxide layer.

Moreover, one aspect of the nonvolatile memory device is a nonvolatile memory device including: a nonvolatile memory element including a first electrode, a second electrode, and a variable resistance layer comprising a metal oxide and interposed between the first electrode and the second electrode; a write unit configured to apply, between the first electrode and the second electrode, a first voltage pulse for changing a resistance state of the nonvolatile memory element from a first state to a second state, and subsequently, apply, between the first electrode and the second electrode, a second voltage pulse which has a same polarity as the first voltage pulse and a voltage an absolute value of which is smaller than an absolute value of a voltage of the first voltage pulse; a determination unit configured to determine, after application of the second voltage pulse, whether the resistance state of the nonvolatile memory element is the second state; and a rewrite unit configured to apply, between the first electrode and the second electrode, a third voltage pulse for changing the resistance state of the nonvolatile memory element from the first state to the second state when the determination unit determines that the resistance state of the nonvolatile memory element is not the second state.

According to this, after the writing is performed to change the resistance state of the nonvolatile memory element from the first state to the second state, the writing for the fluctuation determination is performed, and if it is determined that the resistance value of the nonvolatile memory element is likely to fluctuate, the rewriting is performed. Thus, the effects of the fluctuations are reduced and the data retention characteristics improve.

Hereinafter, embodiments according to the present invention will be described, with reference to the accompanying drawings. It should be noted that embodiments described below are each merely a preferred illustration of the present invention. Values, shapes, materials, components, disposition or a form of connection between the components, steps, and the order of the steps are merely illustrative, and are not intended to limit the present invention. The present invention is limited only by the scope of the appended claims. Moreover, among components of the embodiments below, components not set forth in the independent claims indicating the top level concept of the present invention will be described as optional components.

Hereinafter, preferred embodiments of the present invention will be described, with reference to the accompanying drawings.

### Embodiment 1

### [Configuration of Nonvolatile Memory Element]

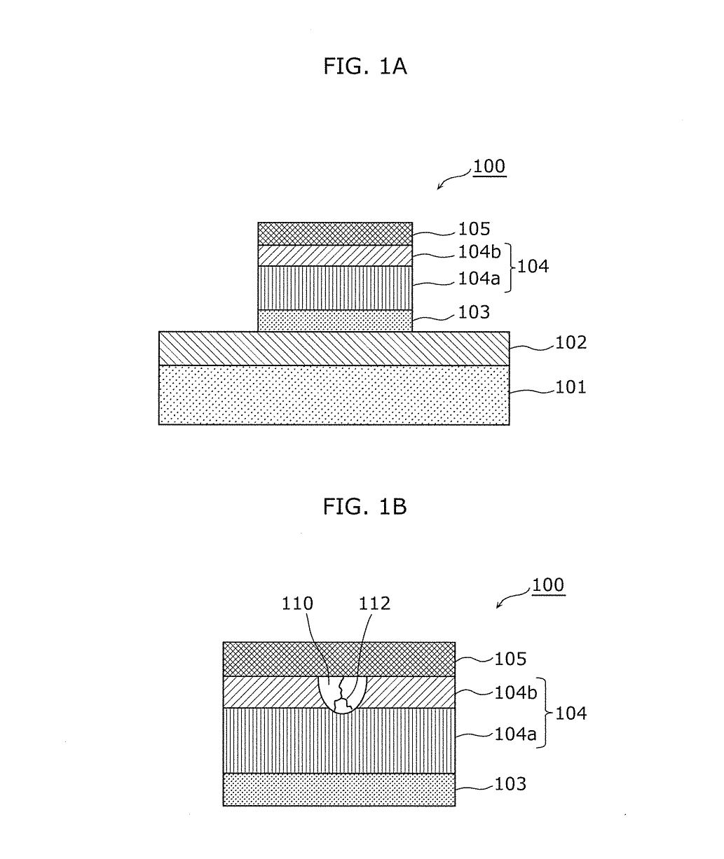

FIG. 1A is a sectional view of the configuration of a nonvolatile memory element according to an embodiment 1 of the present invention.

As shown in FIG. 1A, a nonvolatile memory element 100 according to the present embodiment includes a substrate 101, an interlayer insulating film 102 formed on the substrate 101, a first electrode 103 formed on the interlayer insulating film 102, a second electrode 105, and a variable resistance layer 104 sandwiched between the first electrode 103 and the second electrode 105. It should be noted that while in the figure, the nonvolatile memory element 100 includes the substrate 101 and the interlayer insulating film 102, these components are not necessarily being essential.

The variable resistance layer 104 has a stacked structure including a first metal oxide layer 104a comprising a first metal oxide and a second metal oxide layer 104b comprising a second metal oxide. In the present embodiment, the first metal oxide layer 104a comprises an oxygen-deficient tantalum oxide, and the second metal oxide layer 104b also comprises a tantalum oxide. Here, an oxygen content percentage of the second metal oxide layer 104b is higher than an oxygen content percentage of the first metal oxide layer 104a. In other words, the oxygen deficiency in the first metal oxide layer 104a is higher than the oxygen deficiency in the second metal oxide layer 104b. Thus, the resistance value (to be more accurate, resistivity) of the resistance value of the second metal oxide layer 104b is greater than the resistance value (to be more accurate, resistivity) of the first metal oxide layer 104a.

Preferably, when the compositions of the first metal oxide layer 104a and the second metal oxide layer 104b are represented by TaOₓ and TaO_{y}, respectively, 0<x<2.5 and x<y is satisfied. More preferably, 2.1≦y and 0.8≦x≦1.9 are satisfied to achieve stable resistance change operation of the nonvolatile memory element 100. The composition of the metal oxide layer can be measured by the Rutherford Backscattering Spectrometry.

The nonvolatile memory element 100 having such a configuration is ready for reversely transitioning the resistance state thereof between the high resistance state and the low resistance state by being applied an initial breakdown voltage (initial breakdown), which is greater than or equal to a predetermined voltage, between the first electrode 103 and the second electrode 105 just after manufacture. Due to the initial breakdown, a micro local region 110 the oxygen deficiency of which reversely changes according to the application of the electrical pulse is formed in the second metal oxide layer 104b of the nonvolatile memory element 100 as shown in FIG. 1B. The local region 110 is believed to include a filament 112 formed by oxygen vacancy sites. In other words, the second metal oxide layer 104b has therein a region which has a locally high oxygen vacancy concentration. The filament 112 is a current path (conductive path) through which a current which has a locally high current density flows. It should be noted that FIG. 1B omits illustration of the substrate 101 and the interlayer insulating film 102 shown in FIG. 1A.

In the nonvolatile memory element 100 having undergone the initial breakdown, the resistance change occurs in the second metal oxide layer 104b that is in contact with the second electrode 105 and has higher oxygen concentration than the first metal oxide layer 104a. For example, when a voltage of the second electrode 105 is higher than a voltage of the first electrode 103 by a predetermined voltage or greater, the resistance state of the nonvolatile memory element 100 changes to the high resistance state. Conversely, when the voltage of the first electrode 103 is higher than the voltage of the second electrode 105 by the predetermined voltage or greater, the resistance state of the nonvolatile memory element 100 changes to the low resistance state. In other words, in the present embodiment, the nonvolatile memory element 100 is, by way of example, a bipolar memory element in which the resistance state of the nonvolatile memory element 100 transitions from the high resistance state to the low resistance state, or, from the low resistance state to the high resistance state, according to the polarity of a voltage pulse applied between the first electrode 103 and the second electrode 105.

It should be noted that “resistance state of nonvolatile memory element” strictly means “resistance state of variable resistance layer.”

Here, “oxygen deficiency” refers to a percentage of deficiency of oxygen in a metal oxide relative to an amount of oxygen included in an oxide which has the stoichiometric composition (if there is a plurality of stoichiometric compositions, a stoichiometric composition in which the resistance value is the highest). A metal oxide having a stoichiometric composition is stable and has a higher resistance value as compared to metal oxides that have other compositions.

For example, when the metal is tantalum (Ta), an oxide which has stoichiometric composition by the above definition is represented by Ta₂O₅, and thus can be represented by TaO_{2.5}. The oxygen deficiency in TaO_{2.5} is 0%, and the oxygen deficiency in TaO_{1.5} is as follows: oxygen deficiency=(2.5−1.5)/2.5=40%. A metal oxide comprising excessive oxygen has oxygen deficiency of a negative value. It should be noted that, unless otherwise indicated herein, description will be given assuming that the oxygen deficiency includes positive values, zero, and negative values.

An oxide having a small oxygen deficiency has a high resistance value because the oxide is closer to being an oxide having a stoichiometric composition, and an oxide having a great oxygen deficiency has a low resistance value because the oxide is closer to being a metal included in an oxide.

“Oxygen content percentage” is a ratio of the number of oxygen atoms relative to the total number of atoms. For example, an oxygen content percentage of Ta₂O₅ is a ratio of the number of oxygen atoms relative to the total number of atoms and 71.4 atm % (O/(Ta+O)). Thus, an oxygen content percentage of an oxygen-deficient tantalum oxide is greater than 0 atm % and less than 71.4 atm %. For example, when a metal included in the first metal oxide layer 104a and a metal included in the second metal oxide layer 104b are the same metal, the oxygen content percentages of the first metal oxide layer 104a and the second metal oxide layer 104b correspond with each other. In other words, when the oxygen content percentage of the second metal oxide layer 104b is greater than the oxygen content percentage of the first metal oxide layer 104a, the oxygen deficiency in the second metal oxide layer 104b is smaller than the oxygen deficiency in the first metal oxide layer 104a.

The metal included in the variable resistance layer 104 may be other than tantalum. A transition metal or aluminum (Al) may be employed as the metal included in the variable resistance layer 104. Examples of the transition metal include tantalum (Ta), titanium (Ti), hafnium (Hf), zirconium (Zr), niobium (Nb), tungsten (W), and nickel (Ni). Transition metals can adopt multiple oxidization states, and thus different resistance states can be achieved by the redox reaction.

For example, when a hafnium oxide is used, the resistance value of the variable resistance layer can be stably and rapidly changed, when x of a composition of the first metal oxide layer 104a represented by HfOₓ is 0.9 or greater and 1.6 or less and a value of y of a composition of the second metal oxide layer 104b represented by HfO_{y} is greater than a value of x. In this case, the film thickness of the second metal oxide layer 104b may be 3 to 4 nm.

When a zirconium oxide is used, the resistance value of the variable resistance layer can be stably and rapidly changed, when x of a composition of the first metal oxide layer 104a represented by ZrOₓ is 0.9 or greater and 1.4 or less and a value of y of a composition of the second metal oxide layer 104b represented by ZrO_{y} is greater than a value of x. In this case, the film thickness of the second metal oxide layer 104b may be 1 to 5 nm.

The first metal included in the first metal oxide layer 104a and the second metal included in the second metal oxide layer 104b may be different metals. In this case, the second metal oxide layer 104b may have a smaller oxygen deficiency, namely, higher resistance than the first metal oxide layer 104a. Such a configuration allows the voltage applied between the first electrode 103 and the second electrode 105 for resistance change to be distributed greater to the second metal oxide layer 104b than to the first metal oxide layer 104a. This causes the redox reaction in the second metal oxide layer 104b to being more likely to occur.

If the first metal included in the first metal oxide layer 104a and the second metal included in the second metal oxide layer 104b are different materials, the standard electrode potential of the second metal may be lower than the standard electrode potential of the first metal. The standard electrode potential represents a characteristic in which a higher value of standard electrode potential decreases the susceptibility of the metal oxide layer to oxidize. This causes the redox reaction more likely to occur in the second metal oxide layer 104b the standard electrode potential of which is relatively small. It is believed that in the resistance change phenomenon, the resistance value (oxygen deficiency) of the second metal oxide layer 104b changes because the redox reaction occurs in the micro local region 110 formed in the second metal oxide layer 104b having high resistance and the filament (conductive path) 112 changes.

For example, by using an oxygen-deficient tantalum oxide (TaOₓ) for the first metal oxide layer 104a and a titanium oxide (TiO₂) for the second metal oxide layer 104b, stable resistance change operation is obtained. Titanium (standard electrode potential=−1.63 eV) is a material that has a lower standard electrode potential than tantalum (standard electrode potential=−0.6 eV). As described above, by using a metal oxide that has a lower standard electrode potential than the first metal oxide for the second metal oxide layer 104b, the redox reaction is more likely to occur in the second metal oxide layer 104b. As another combination, an aluminum oxide (Al₂O₃) can be used for the second metal oxide layer 104b. For example, an oxygen-deficient tantalum oxide (TaOₓ) may be used for the first metal oxide layer 104a and an aluminum oxide (Al₂O₃) may be used for the second metal oxide layer 104b.

It is believed that, as described above, in any of the resistance change phenomenon in the variable resistance layer 104 which includes the stacked structure, the resistance value of the second metal oxide layer 104b changes because the redox reaction occurs in the micro local region 110 formed in the second metal oxide layer 104b having high resistance and the filament (conductive path) 112 in the micro local region 110 changes.

Specifically, when a positive voltage relative to the first electrode 103 is applied to the second electrode 105 connected to the second metal oxide layer 104b, oxygen ions in the variable resistance layer 104 are attracted toward the second metal oxide layer 104b. This causes oxidization reaction in the micro local region 110 formed in the second metal oxide layer 104b and the oxygen deficiency in the second metal oxide layer 104b reduces. It is believed that, as a result, the filament 112 is hardly formed in the local region 110, which increases the resistance value of the second metal oxide layer 104b, that is, the resistance value of the nonvolatile memory element 100.

Conversely, when a negative voltage relative to the first electrode 103 is applied to the second electrode 105 connected to the second metal oxide layer 104b, oxygen ions in the second metal oxide layer 104b are pushed toward the first metal oxide layer 104a. This causes reduction reaction in the micro local region 110 formed in the second metal oxide layer 104b and the oxygen deficiency in the second metal oxide layer 104b increases. It is believed that, as a result, the filament 112 is likely to be formed in the local region 110, which decreases the resistance value of the second metal oxide layer 104b, that it, the resistance value of the nonvolatile memory element 100.

The second electrode 105 connected to the second metal oxide layer 104b the oxygen deficiency of which is smaller than the first metal oxide layer 104a includes a material such as platinum (Pt), iridium (Ir), and palladium (Pd), that has a high standard electrode potential as compared to the metal included in the second metal oxide layer 104b and the material included in the first electrode 103. Moreover, the first electrode 103 connected to the first metal oxide layer 104a that has higher oxygen deficiency than the second metal oxide layer 104b may include a material such as tungsten (W), nickel (Ni), tantalum (Ta), titanium (Ti), aluminum (Al), tantalum nitride (TaN), and titanium nitride (TiN) that has a low standard electrode potential as compared the metal included in the first metal oxide layer 104a. A material having a higher standard electrode potential represents characteristics as being hardly to oxidize.

In other words, the relationship between a standard electrode potential Ve2 of the second electrode 105, a standard electrode potential Vr2 of the metal included in the second metal oxide layer 104b, a standard electrode potential Vr1 of the metal included in the first metal oxide layer 104a, and a standard electrode potential Ve1 of the first electrode 103 may satisfy Vr2<Ve2 and Ve1<Ve2. Furthermore, Ve2>Vr2 and Vr1≦Ve1 may be satisfied.

According to the above configuration, the redox reaction selectively occurs in the second metal oxide layer 104b near an interface between the second electrode 105 and the second metal oxide layer 104b, and stable resistance change phenomenon is obtained.

Moreover, preferably, the dielectric constant of the second metal oxide layer 104b is greater than the dielectric constant of the first metal oxide layer 104a. Alternatively, preferably, the bandgap of the second metal oxide layer 104b is smaller than the bandgap of the first metal oxide layer 104a. For example, TiO₂ (relative dielectric constant=95, bandgap=3.1 ev) has a greater relative dielectric constant and a smaller bandgap than Ta₂O₅ (relative dielectric constant=26, bandgap=4.4 eV). In general, a material that has a greater relative dielectric constant is more likely to break down (the initial breakdown) than a material having a smaller relative dielectric constant, and a material that has a smaller bandgap is more likely to break down than a material that has a greater bandgap. Thus, a material that has a greater relative dielectric constant or a material that has a smaller bandgap can reduce the initial breakdown voltage.

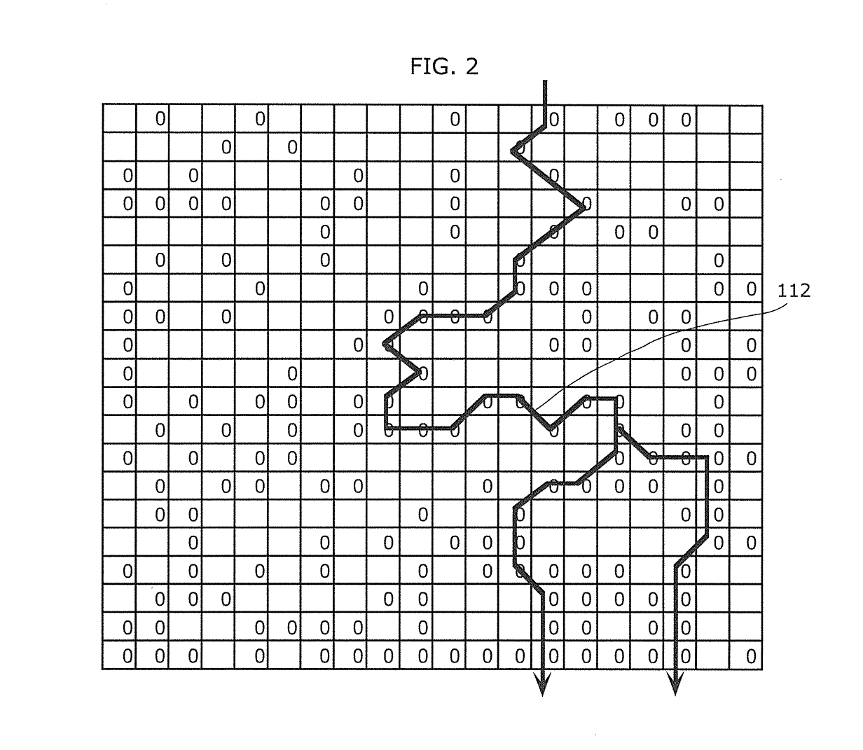

By using a metal oxide that satisfies either or both the above conditions (i.e., conditions regarding the dielectric constant and bandgap) for the second metal oxide layer 104b, the breakdown strength of the second metal oxide layer 104b is less than that of the first metal oxide layer 104a, thereby reducing the initial breakdown voltage. This is because, as shown in FIG. 1 illustrating NPL 3 (J. McPherson et al., IEDM 2002, p. 633-636) for example, the correlation is seen between the breakdown strength and the dielectric constant of the metal oxide layer that the greater the dielectric constant is, the smaller the breakdown strength is. This is also because, as shown in FIG. 2 illustrating NPL 3, the correlation is seen between the breakdown strength and the bandgap of the metal oxide layer that the greater the bandgap is the greater the breakdown strength is.

FIG. 2 is a diagram illustrating the formation of the above-described filament 112, showing, by way of example, a result of simulation using the percolation model. Here, it is postulated that the filament (conductive path) 112 is formed of oxygen vacancy sites in the variable resistance layer 104 (particularly, in the second metal oxide layer 104b) being connected to each other. The percolation model is based on the theory that, postulating random distribution of the oxygen vacancy sites (hereinafter, simply referred to as “vacancy sites”) or the like in the variable resistance layer 104, the connection between the vacancy sites or the like is formed if the density of the vacancy sites or the like exceeds a threshold. Here, “vacancy” means that oxygen is deficient in a metal oxide, and “density of vacancy sites” corresponds also to the oxygen deficiency. In other words, the greater the oxygen deficiency is, the greater the density of the vacancy sites is.

Here, oxygen ion sites in the variable resistance layer 104 are postulated, by way of approximation, as regions (sites) partitioned in grid, and the filament 112 which is formed by probabilistically formed vacancy sites is obtained by simulation. In FIG. 2, sites that include “0” represent the vacancy sites formed in the variable resistance layer 104. On the other hand, empty sites represent sites occupied by oxygen ions and means highly resistant regions. A cluster of the vacancy sites indicated by arrows (a collection of vacancy sites connected to one another in top-down, left-right, and diagonal directions in a site range) indicates the filament 112 which is formed in the variable resistance layer 104 when a voltage is applied to the variable resistance layer 104 in the top-down direction in the figure, that is, indicates paths through which a current flows. As shown in FIG. 2, the filament 112 which allows a current to flow between the top and bottom surfaces of the variable resistance layer 104 includes a cluster of the vacancy sites which connects the top end and the bottom end of the randomly distributed vacancy sites. Based on the percolation model, the number of filaments 112 and the shape are probabilistically formed. The number of filaments 112 and the shape represent the variations in resistance value of the variable resistance layer 104.

[Method for Manufacturing Nonvolatile Memory Element]

Next, an example of a method for manufacturing the nonvolatile memory element 100 according to the present embodiment will be described. It should be noted that steps, materials, film thicknesses, and other conditions in each processing described below are merely illustrative, and the present embodiment is not limited thereto.

First, an interlayer insulating film 102 having a thickness of 200 nm is formed on a substrate 101 which is of single-crystal silicon by a thermal oxidation method. Then, a Pt thin film having a thickness of 100 nm is formed as a first electrode 103 on the interlayer insulating film 102 by a sputtering method. It should be noted that an adhesion layer comprising Ti, TiN, or the like may be formed between the first electrode 103 and the interlayer insulating film 102 by a sputtering method. Thereafter, the first metal oxide layer 104a which is of oxygen-deficient is formed on the first electrode 103 by, for example, a reactive sputtering method using a Ta target.

Next, for example, by modification due to oxidization of a top surface of the first metal oxide layer 104a or by a reactive sputtering method using a Ta target, the second metal oxide layer 104b having a smaller oxygen deficiency than the first metal oxide layer 104a is formed on the surface of the first metal oxide layer 104a. The stacked structure including the first metal oxide layer 104a and the second metal oxide layer 104b forms the variable resistance layer 104.

Herein, to appropriately reduce the initial resistance value, preferably, the thickness of the second metal oxide layer 104b is less than or equal to about 8 nm, and, to obtain stable resistance change, preferably, greater than or equal to about 1 nm. For example, the second metal oxide layer 104b has a thickness of 6 nm.

Next, for example, a Pt thin film having a thickness of 150 nm is formed as the second electrode 105 on the second metal oxide layer 104b by a sputtering method.

Thus, the nonvolatile memory element 100 can be fabricated in which the variable resistance layer 104 employing an oxygen-deficient Ta oxide is sandwiched between the first electrode 103 and the second electrode 105.

[Resistance Value Fluctuation Phenomenon and its Characteristics]

Hereinafter, the knowledge newly found by the inventors through experiments with respect to the retention characteristics of the resistance state of the nonvolatile memory element 100 fabricated as described above will be described in detail. It should be noted that voltage values, pulse widths, the number of times voltages are applied, and resistance values described below merely show an experimental example describing the knowledge, and the present embodiment is not limited thereto.

<Resistance Value Setting>

The resistance change was caused by applying an electrical pulse signal between the first electrode 103 and the second electrode 105 of the nonvolatile memory element 100. The following will describe a case where a voltage pulse is used as the electrical pulse signal. It should be noted that, herein, the polarity of the voltage is represented relative to the first electrode 103. In other words, a voltage where a high voltage is applied to the second electrode 105 is “positive,” and a voltage where a low voltage is applied to the second electrode 105 is “negative,” relative to the first electrode 103. The resistance state of the nonvolatile memory element 100 changes to the high resistance state when the positive voltage is applied to the second electrode 105, and changes to the low resistance state when the negative voltage is applied to the second electrode 105.

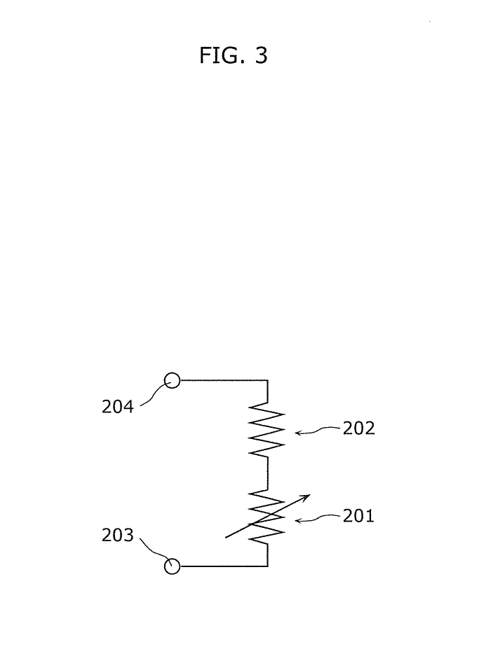

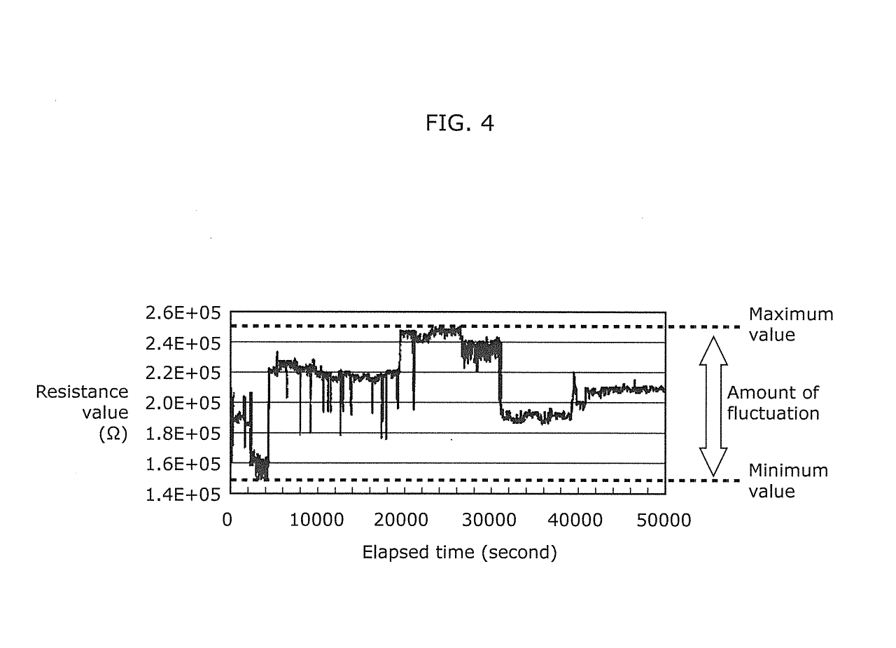

In the present experimental example, as shown in FIG. 3, a voltage was applied to a variable resistance nonvolatile memory element 201 (corresponding to the nonvolatile memory element 100 described above) connected to load resistance 202 of various values from 0 to 6.4 kΩ in series. Specifically, voltage pulses which have temporal length (i.e., pulse width) of 100 ns and the magnitude of +2.5 V and −2.0 V were alternately applied to a terminal 203 and a terminal 204 shown in FIG. 3 100 times.

There are two reasons why the load resistance 202 is connected as described above to the variable resistance nonvolatile memory element 201. The first reason is that connecting the load resistance 202 changes the set resistance value of the nonvolatile memory element 201, allowing for information over a wide resistance range to be obtained. In a sample used in the present embodiment, the nonvolatile memory element 201 has a characteristic in which a low resistance value is equal to a value of the load resistance 202, and, in many cases, a high resistance value is about 10 to 100 times greater than the low resistance value. Thus, the smaller the load resistance 202 is, the smaller the set resistance value of the nonvolatile memory element 201 is, and vice versa.

The second reason is that it was assumed to grasp the fluctuation phenomenon in resistance value when the nonvolatile memory element 201 is in actual use. In use, the variable resistance nonvolatile memory element is not solely used but is used in a state being connected to a transistor and a diode having certain amounts of resistance values. In addition, there is not a little resistance due to the lines. Therefore, the load resistance 202 was connected assuming that these external load resistances which occur when the variable resistance nonvolatile memory element is in use.

As described above, the resistance value of the nonvolatile memory element 201 was set to the high resistance state (the resistance value RH) and the low resistance state (the resistance value RL). To set the resistance value to the high resistance state, voltage pulses of +2.5 V and −2.0 V were alternately applied to the nonvolatile memory element 201 100 times, and last, the voltage pulse of +2.5 V was applied one time. On the other hand, to set the resistance value to the low resistance state, the voltage pulse of −2.0 V was last applied to the nonvolatile memory element 201 one time. Here, the pulse width was in both cases 100 ns.

<Measurement of Short-time Variation (Fluctuation) of Resistance Value>

The nonvolatile memory element 201 the resistance value of which is set as described above was kept at room temperature and a voltage of 50 mV was applied thereto at every 20 seconds to measure the resistance value of the nonvolatile memory element 201. Using such a low voltage of the order of 50 mV does not change the resistance value of the nonvolatile memory element 201.

FIG. 4 is a diagram showing the variations (i.e., fluctuation) in resistance value of the nonvolatile memory element 201 from 0 to 50000 seconds after the resistance value of the nonvolatile memory element 201 is set to the high resistance state while being connected to the load resistance of 6.4 kΩ. Hereinafter, the resistance value of the nonvolatile memory element 201 immediately after the resistance value of the nonvolatile memory element 201 is set to the high resistance state will be referred to as the set resistance value. In the example shown in FIG. 4, the set resistance value was about 170 kΩ. Referring to FIG. 4, it can be seen that the resistance value increases and decreases over time, causing the fluctuation phenomenon. Specifically, the resistance value is a minimum of 150 kΩ about 2000 seconds after start of the measurement, and is a maximum of 250 kΩ about 20000 seconds after the start.

While the variations in resistance value after the resistance value of the nonvolatile memory element 201 is set to the high resistance state is shown in FIG. 4, the inventors has confirmed that similar variations in resistance value also when the resistance value of the nonvolatile memory element 201 is set to the low resistance state.

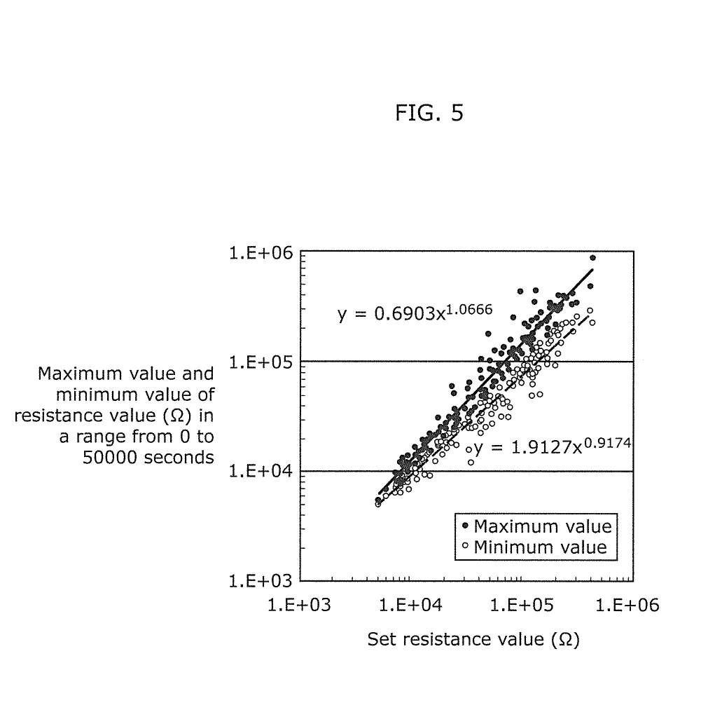

The similar measurement as the above was conducted with the load resistance 202 of 0Ω (no load), 1700Ω, 2150Ω, 3850Ω, 4250Ω, and 6400Ω connected to the nonvolatile memory element 201. The results are summarized in FIG. 5. In FIG. 5, the set resistance value of the nonvolatile memory element 201 is indicated on the horizontal axis. Indicated on the vertical axis are the maximum values and the minimum values of the resistance value of the nonvolatile memory element 201 that varied from 0 to 50000 seconds after the resistance value is set to the high resistance state. Here, data indicated by solid black circles indicate the maximum values of the resistance value, and data indicated by open circles indicate the minimum values of the resistance value. Results (approximate curves) of fitting each data are also indicated. A solid line shows the result of fitting the maximum values of the resistance value, and a dashed line shows the result of fitting the minimum values of the resistance value.

Referring to FIG. 5, it can be seen that, for example, the fluctuation in resistance value where the set resistance value was 100 kΩ changed the resistance value from about 80 kΩ to about 200 kΩ on average. In the figure, a relation (approximation) obtained by fitting is also shown. In the relation, x represents a maximum value or a minimum value of the set resistance value and y represents a maximum value or a minimum value of the resistance value.

<Prediction on Fluctuation Susceptibility>

As described above, the resistance change phenomenon is believed to occur by a micro filament being formed in the variable resistance layer 104, the redox reaction being caused in the micro filament, and the resistance value of the variable resistance layer 104 being changed. Thus, the fluctuation phenomenon now found by the inventors is also believed to occur by the conduction state in the micro filament being changed due to some effect. Specifically, it is believed that the fluctuations may be caused by incomplete bonds or detachment of oxygen. It is also believed that electric potential may be changed and the resistance state may be fluctuated by electrons being captured or released by dangling bonds present in the micro filament. Thus, to a greater or lesser extent, it is inferred that the fluctuation phenomenon unavoidably occurs if the variable resistance nonvolatile memory element is configured to increase or decrease the resistance value in relation to the micro filament.

Based on the above knowledge, the inventors have newly found the following nature of the fluctuation phenomenon.

As described above, when the fluctuation phenomenon is caused by electrons being captured or released by dangling bonds present in the micro filament, the fluctuation phenomenon can be induced by intentionally capturing and releasing the electrons. Specifically, a negative polarity voltage pulse is applied to the second electrode 105 to inject electrons into a filament, thereby causing dangling bonds in the filament to capture the electrons. This blocks the conduction path (filament). Thus, the resistance value increases. On the other hand, a positive polarity voltage pulse is applied to the second electrode 105, thereby releasing the electrons from the filament. This restores the conduction path (filament). Thus, the resistance value decreases. In such a manner, the resistance value varies even by a voltage that has smaller amplitude than a normal write voltage, and the fluctuation phenomenon is induced. It should be noted that, desirably, the voltage pulse for inducing the fluctuation phenomenon has a voltage value sufficient such that a current flowing through the nonvolatile memory element is 1 μA or greater.

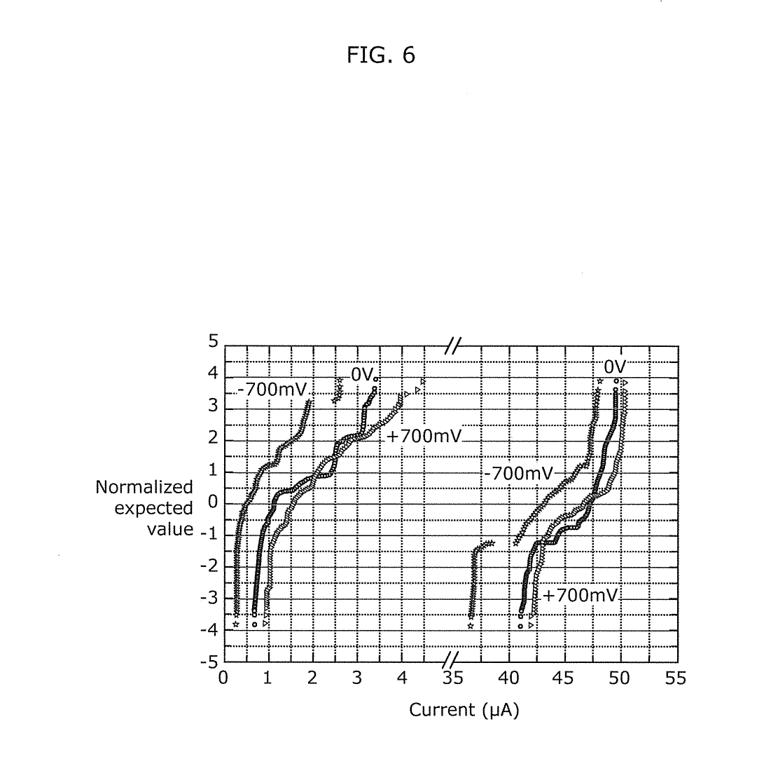

Hereinafter, the voltage pulse for inducing the fluctuation phenomenon as described above will be expressed as a fluctuation determination voltage pulse. The fluctuation phenomenon is induced by the fluctuation determination voltage pulse in the nonvolatile memory element the resistance value of which is likely to fluctuate, and the fluctuation phenomenon is not induced in the nonvolatile memory element the resistance value of which hardly fluctuates even though the fluctuation determination voltage pulse is applied thereto. FIG. 6 shows an example where the resistance value of the nonvolatile memory element varies due to the fluctuation determination voltage pulse. The left of FIG. 6 is a diagram showing the relationship between a current value (the horizontal axis) and normal distribution of the current value (normalized expected values; the vertical axis) obtained by setting the resistance state of the nonvolatile memory element 100 to the high resistance state, followed by applying the fluctuation determination voltage pulse to the nonvolatile memory element 100, and then performing a read process. The right of FIG. 6 is a diagram showing the relationship between a current value (the horizontal axis) and normal distribution of the current value (normalized expected values; the vertical axis) obtained by setting the resistance state of the nonvolatile memory element 100 to the low resistance state, followed by applying the fluctuation determination voltage pulse to the nonvolatile memory element 100, and then performing the read process. Here, to set the resistance state of the nonvolatile memory element 100 to the high resistance state, a high resistance writing voltage pulse of +2.5 V for 200 ns was used and to set the resistance state of the nonvolatile memory element 100 to the low resistance state, a low resistance writing voltage pulse of −1.5 V for 200 ns was used. Moreover, a voltage pulse of +700 mV for 200 ns was used as the fluctuation determination voltage pulse for inducing the fluctuation phenomenon that decreases the resistance value, and a voltage pulse of −700 mV for 200 ns was used as the fluctuation determination voltage pulse for inducing the fluctuation phenomenon that increases the resistance value.

FIG. 6 also shows a case, as comparison, where the read process was performed without application of the fluctuation determination voltage pulse (sets of plots labeled “0 V” in the figure). Referring to FIG. 6, it can be seen that the current value is increased (i.e., the resistance value of the nonvolatile memory element 100 is decreased) by application of the fluctuation determination voltage pulse of +700 mV in both cases where the resistance state is the high resistance state and the low resistance state. Moreover, it can be seen that the current value is decreased (i.e., the resistance value of the nonvolatile memory element 100 is increased) by application of the fluctuation determination voltage pulse of −700 mV in both cases where the resistance state is the high resistance state and the low resistance state.

In this manner, using the fluctuation determination voltage pulse can vary the resistance value of the nonvolatile memory element. Here, when the result of application of the fluctuation determination voltage pulse shows that the greater the number of times data read error occurs, the greater the set resistance value changes, the resistance value of the nonvolatile memory element may be likely to fluctuate. On the other hand, when the result of application of the fluctuation determination voltage pulse shows no change in the set resistance value, or the set resistance value changes only within a rage where no data read error occurs, the resistance value of the nonvolatile memory element may hardly fluctuate. In this manner, by using the fluctuation determination voltage pulse, it can be determined whether the resistance value of the nonvolatile memory element is likely to fluctuate.

[Data Write Method for Writing Data to Nonvolatile Memory Element]

A data write method according to the present embodiment has been found based on the above-described new knowledge. Hereinafter, the data write method according to the present embodiment will be described.

It is believed that when the resistance value of the nonvolatile memory element is likely to fluctuate, the set resistance value largely changes and there is a high possibility of occurrence of data read error. To obviate such inconvenience, in the present embodiment, it is determined, after data is written to the nonvolatile memory element, whether the resistance value of the nonvolatile memory element is likely to fluctuate, and it is determined as a result that the resistance value of the nonvolatile memory element is likely to fluctuate, data rewriting is performed. This can reduce the variations in resistance value due to the fluctuation phenomenon, and improve the data retention characteristics. Hereinafter the data write method for writing data to the nonvolatile memory element according to the present embodiment will be described with reference to flowcharts.

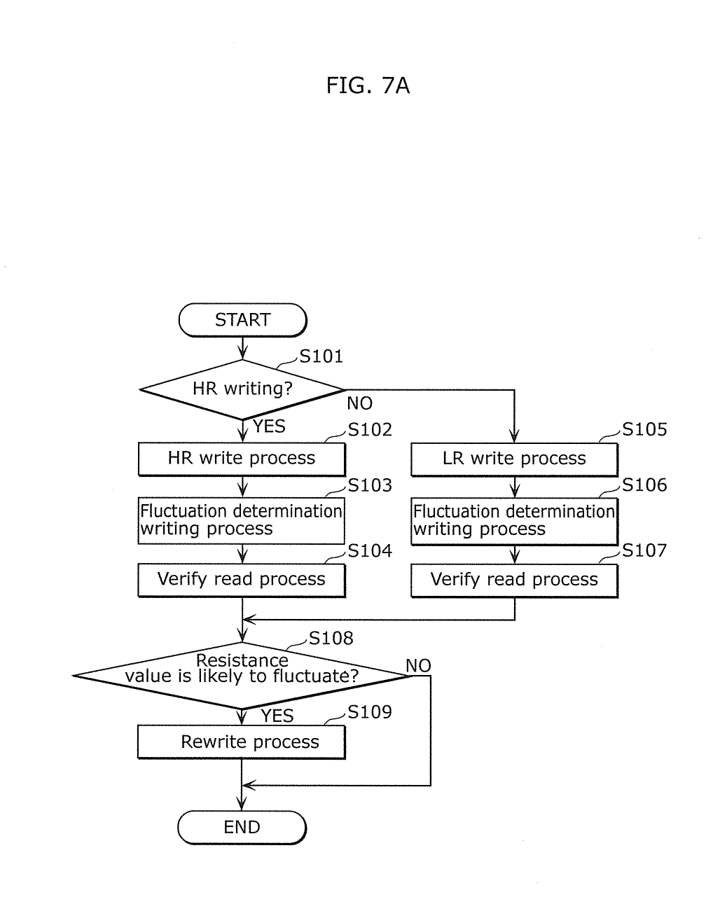

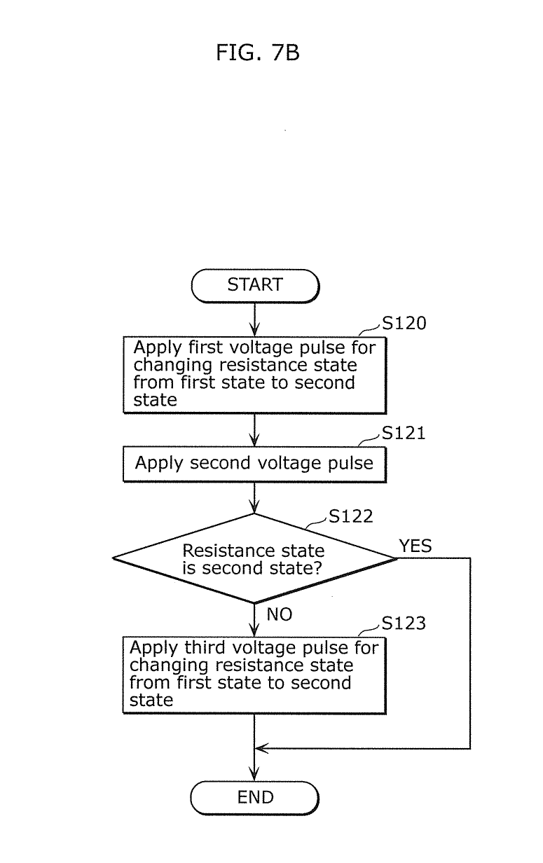

FIG. 7A is a flowchart illustrating the procedure of the data write process of the nonvolatile memory element according to the embodiment 1 of the present invention. As illustrated in FIG. 7A, first, it is determined whether the data write process is writing (HR writing) for setting the resistance state of the nonvolatile memory element 100 to the high resistance state or writing (LR writing) for setting the resistance state of the nonvolatile memory element 100 to the low resistance state (S101). Here, when it is determined that the writing is the HR writing (YES in S101), the HR write process is performed (S102). In the HR writing, for example, a positive polarity write voltage pulse (for example, +2.0 V) is applied between the first electrode 103 and the second electrode 105. Next, the fluctuation determination voltage pulse is applied between the electrodes (S103). The fluctuation determination voltage pulse is a voltage pulse that has the same polarity as the HR writing voltage pulse, and a voltage value of which has a smaller absolute value than the HR writing voltage pulse. The fluctuation determination voltage pulse in step S103 is, for example, +0.7 V. It should be noted that, hereinafter, the write process using the fluctuation determination voltage pulse will be referred to as a fluctuation determination writing process.

As described above, for the HR writing in the present embodiment, the fluctuation determination voltage pulse that has the positive polarity (i.e., the same polarity as the HR writing voltage pulse) is used in the fluctuation determination writing process. When the positive polarity fluctuation determination voltage pulse is applied between the electrodes, electrons are released from the filament formed in the variable resistance layer 104, and as result, the conduction path is restored and the resistance value decreases. In this manner, since the positive polarity fluctuation determination voltage pulse provides benefit to decrease the resistance value, the fluctuation phenomenon in which the resistance state is set to the low resistance state is induced in the nonvolatile memory element 100 in the high resistance state.

Next, a read voltage pulse is applied between the electrodes, a value of the current flowing through the variable resistance layer 104 at which time is detected, and a verify read process for determining whether the nonvolatile memory element 100 is in the high resistance state or the low resistance state is performed (S104). Then, based on the result of the verify read process, it is determined if the high resistance state set by the HR write process in step S102 has been lost, that is, whether the resistance value of the nonvolatile memory element 100 is likely to fluctuate (S108). Here, when it is determined that the nonvolatile memory element 100 is in the low resistance state rather than the high resistance state, that is, that the resistance value of the nonvolatile memory element 100 is likely to fluctuate (YES in S108), a rewrite process for re-applying the HR writing voltage pulse between the electrodes is performed (S109). This can set the nonvolatile memory element 100 back to a desired high resistance state. On the other hand, when it is determined by the verify read process (S104) that the nonvolatile memory element 100 is maintained in the high resistance state, that is, that the resistance value of the nonvolatile memory element 100 hardly fluctuates (NO in S108), the processing ends.

When it is determined in step S101 that the writing is not the HR writing, that is, that the writing is the LR writing (NO in S101), the LR write process is performed (S105). In the LR writing, for example, a negative polarity write voltage pulse (for example, −2.4 V) is applied between the first electrode 103 and the second electrode 105. Next, the fluctuation determination voltage pulse is applied between the electrodes (S106). The fluctuation determination voltage pulse is a voltage pulse that has the same polarity as the LR writing voltage pulse, and a voltage value of which has a smaller absolute value than the LR writing voltage pulse. The fluctuation determination voltage pulse in S106 is, for example, −0.7 V.

As described above, for the LR writing in the present embodiment, the fluctuation determination voltage pulse that has the negative polarity (i.e., the same polarity as the LR writing voltage pulse) is used in the fluctuation determination writing process. When the negative polarity fluctuation determination voltage pulse is applied between the electrodes, electrons are injected into the filament formed in the variable resistance layer 104, and as result, the conduction path is blocked and the resistance value increases. In this manner, since the negative polarity fluctuation determination voltage pulse provides benefit to increase the resistance value, the fluctuation phenomenon is induced in the nonvolatile memory element 100 in the low resistance state.

Next, the same verify read process as in S104 is performed (S107). Then, based on the result of the verify read process, it is determined if the low resistance state set by the LR writing in step S105 has been lost, that is, whether the resistance value of the nonvolatile memory element 100 is likely to fluctuate (S108). Here, when it is determined, by the verify read process (S107), that the nonvolatile memory element 100 is in the high resistance state rather than the low resistance state, that is, that the resistance value of the nonvolatile memory element 100 is likely to fluctuate (YES in S108), a rewrite process for re-applying the LR writing voltage pulse between the electrodes is performed (S109). This can set the nonvolatile memory element 100 back to a desired low resistance state. On the other hand, if it is determined by the verify read process (S107) that the nonvolatile memory element 100 is maintained in the low resistance state, that is, that the resistance value of the nonvolatile memory element 100 hardly fluctuates (NO in S108), the processing ends.

FIG. 7B corresponds to the summarization of the procedure shown in the flowchart illustrated in FIG. 7A. In other words, a flowchart in which the processing performed in the HR writing and the processing performed in the LR writing are commonly shared is shown.

First, a first voltage pulse (a write voltage pulse) for changing the resistance state of the nonvolatile memory element 100 from a first state to a second state is applied between the first electrode 103 and the second electrode 105 (a first application step S120). In other words, the write process (S102 or S105 of FIG. 7A) is performed.

Next, a second voltage pulse (the fluctuation determination voltage pulse) that has the same polarity as the first voltage pulse and a voltage value of which has a smaller absolute value than the first voltage pulse is applied between the first electrode 103 and the second electrode 105 (a second application step S121). In other words, the fluctuation determination writing process (S103 or S106 in FIG. 7A) is performed.

Then, it is determined whether the resistance state of the nonvolatile memory element 100 is the second state (a determination step S122). In other words, the verify read process (S104 or S107 in FIG. 7A) and the determination as to the fluctuation susceptibility (S108 in FIG. 7A) are performed.

As a result, when it is determined in the determination step S122 that the resistance state of the nonvolatile memory element 100 is not the second state (No in S122), a third voltage pulse (a write voltage pulse) for changing the resistance state of the nonvolatile memory element 100 from the first state to the second state is applied between the first electrode 103 and the second electrode 105 (a third application step S123). In other words, the rewrite process (S109 in FIG. 7A) is performed. On the other hand, when it is determined in the determination step S122 that the resistance state of the nonvolatile memory element 100 is the second state (Yes in S122), the processing ends.

Here, when the flowchart in the diagram is applied to the HR writing, the first state corresponds to the low resistance state, and the second state corresponds to the high resistance state. When the flowchart in the diagram is applied to the LR writing, on the other hand, the first state corresponds to the high resistance state, and the second state corresponds to the low resistance state.

It should be note that while the third voltage pulse typically has the same voltage value as the first voltage pulse, an absolute value of the voltage value of the third voltage pulse may be greater than an absolute value of the voltage value of the first voltage pulse to more assure the rewriting.

Moreover, the second application step S121 and the determination step S122 may be repeated after the third application step S123. In other words, the third application step S123, the second application step S121, and the determination step S122 may be repeated until it is determined in the determination step S122 that the resistance state of the nonvolatile memory element 100 is the second state.

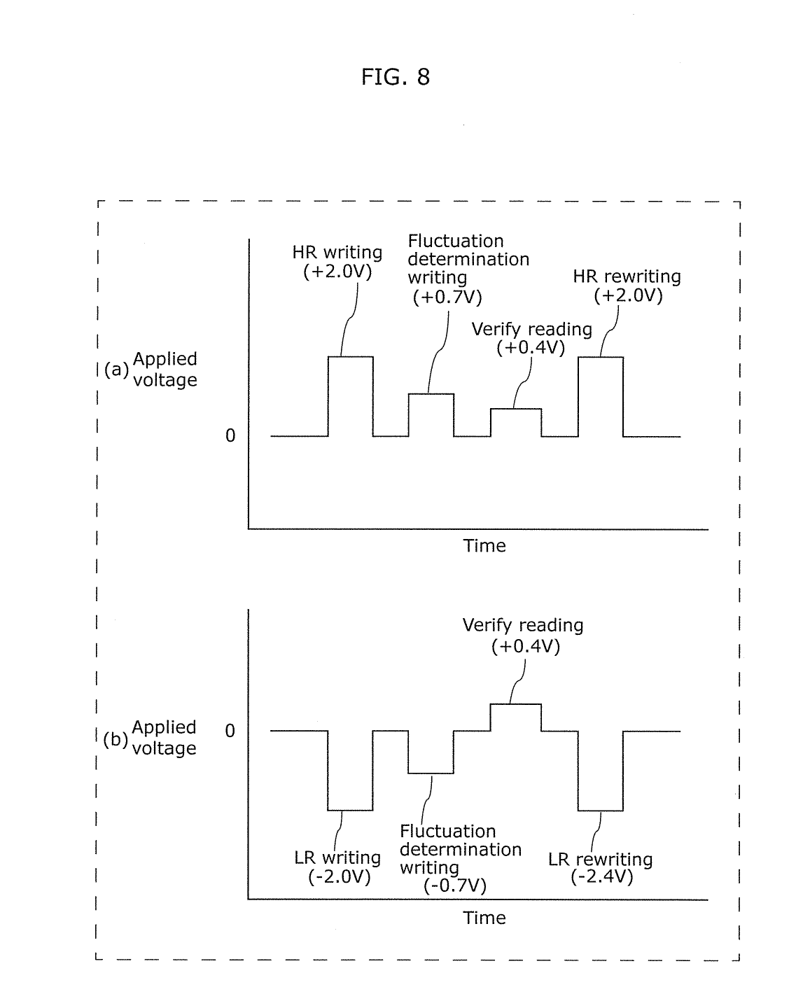

Part (a) of FIG. 8 is a diagram illustrating the application of the voltage pulse in the HR writing. Part (b) of FIG. 8 is a diagram illustrating the application of the voltage pulse in the LR writing. As shown in (a) of FIG. 8, in the present embodiment, after the HR write process (S102) and before the verify read process (S104), the fluctuation determination writing process (S103) is performed which writes, to the nonvolatile memory element 100, the positive polarity voltage pulse of a lower voltage value than the HR write process in absolute value. Then, when it is determined based on a result of the verify read process thereafter that the resistance value of the nonvolatile memory element 100 is likely to fluctuate, the rewrite process (S109) is performed. Likewise, as shown in (b) of FIG. 8, after the LR write process (S105) and before the verify read process (S107), the fluctuation determination writing process (S106) is performed which writes, to the nonvolatile memory element 100, the negative polarity voltage pulse of a lower voltage value than the LR write process in absolute value. Then, when it is determined based on the result of the verify read process that the resistance value of the nonvolatile memory element 100 is likely to fluctuate, the rewrite process (S109) is performed.

As described above, in the present embodiment, when writing data to the nonvolatile memory element 100, normal writing is performed and then the fluctuation determination writing is performed, and, if it is determined that the resistance value of the nonvolatile memory element 100 is likely to fluctuate, data rewriting is performed, thereby improving the data retention characteristics.

[Voltage Value of Fluctuation Determination Voltage Pulse]

Hereinafter, desired ranges of the voltage values of the fluctuation determination voltage pulses for use in the HR writing and the LR writing will be described.

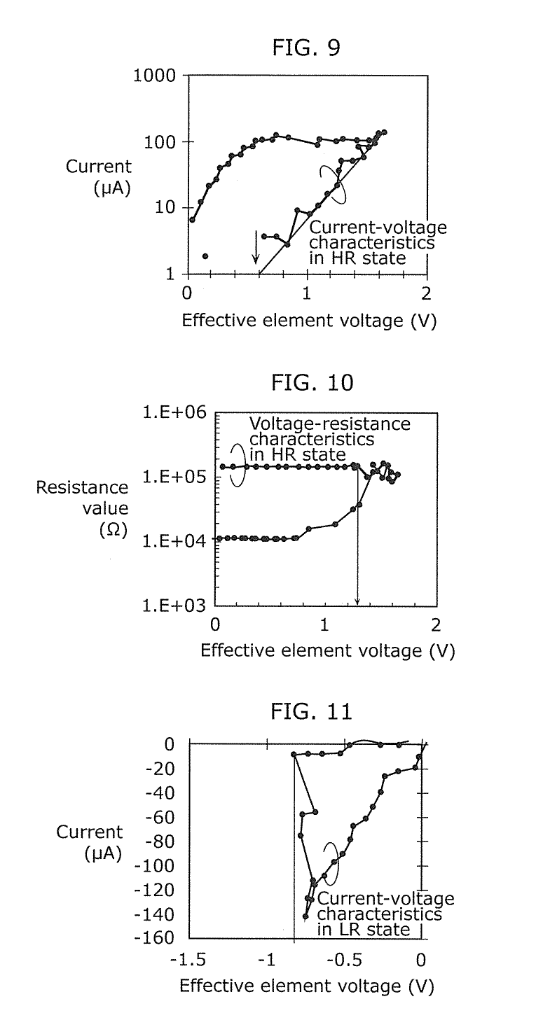

FIG. 9 is a diagram showing an example of the relationship between an effective voltage (“Effective element voltage” on the horizontal axis) which is a voltage across the nonvolatile memory element and the value of the current flowing through the nonvolatile memory element (the vertical axis) when the positive polarity voltage pulse is applied to the nonvolatile memory element in the high resistance state, and FIG. 10 is also a diagram showing an example of the relationship between the effective voltage (“Effective element voltage” on the horizontal axis) and the resistance value (the vertical axis) of the nonvolatile memory element. In the example shown in FIG. 9 where the nonvolatile memory element is in the high resistance state, application of a voltage of +0.6 V starts the current to flow, allowing for injection and release of electrons. Thus, to induce the fluctuation phenomenon, preferably, a voltage value V1 of the fluctuation determination voltage pulse is greater than or equal to +0.6 V. In the example shown in FIG. 10 where the nonvolatile memory element is in the high resistance state and a voltage exceeding +1.3 V is applied thereto, the breakdown and the resistance change to the high resistance state conflict, and the resistance value largely varies, ending up being unstable. Thus, to obviate such the variations in resistance value, preferably, the voltage value V1 of the fluctuation determination voltage pulse is less than or equal to +1.3 V. Thus, preferably, the voltage value V1 of the fluctuation determination voltage pulse for use in the HR writing satisfies 0.6 V≦|V1|≦1.3 V.

In other words, in the HR writing, preferably, the absolute value of the voltage value of the second voltage pulse (a write voltage pulse) is greater than or equal to a minimum voltage (here, 0.6 V) at which, when a voltage is applied between the first electrode 103 and the second electrode 105, a current starts flowing through the nonvolatile memory element 100 where the resistance state of the nonvolatile memory element 100 is the high resistance state, and less than or equal to a maximum voltage (here, 1.3 V) at which the breakdown is not caused in the nonvolatile memory element 100 in the high resistance state when a voltage is applied between the first electrode 103 and the second electrode 105.

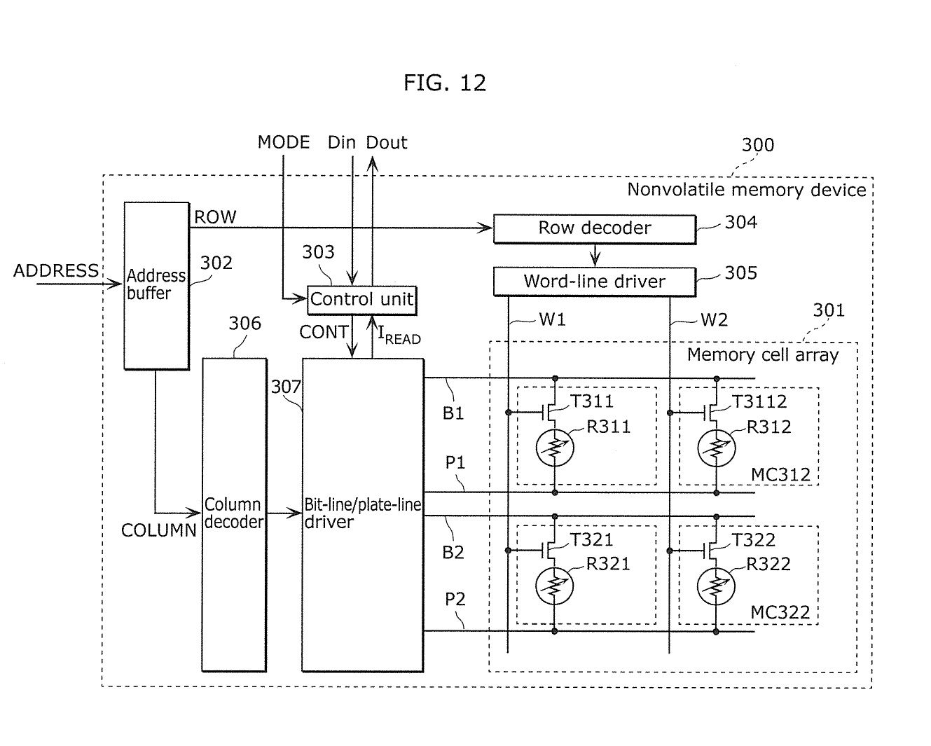

FIG. 11 is a diagram showing an example of the relationship between an effective voltage (“Effective element voltage” on the horizontal axis) which is a voltage across the nonvolatile memory element and the value of the current flowing through the nonvolatile memory element (the vertical axis) when the negative polarity voltage pulse is applied to the nonvolatile memory element alone in the low resistance state. In the example shown in FIG. 11, when the nonvolatile memory element is in the low resistance state, a current starts flowing through the nonvolatile memory element 100 even at a voltage of the order of −0.05 V, allowing for injection and release of electrons. Thus, to induce the fluctuation phenomenon, preferably, a voltage value V2 of the fluctuation determination voltage pulse is greater than or equal to −0.05 V (in absolute value). Moreover, in the example shown in FIG. 11, application of the voltage exceeding −0.75 V causes the progression of the resistance change to the low resistance state, ending up with the resistance value smaller than the set value. Thus, preferably, the voltage value V2 of the fluctuation determination voltage pulse is less than or equal to −0.75 V (in absolute value). Thus, preferably, the voltage value V2 of the fluctuation determination voltage pulse for use in the LR writing satisfies 0.05 V≦|V2|≦0.75.

In other words, in the HR writing, preferably, the absolute value of the voltage value of the second voltage pulse (a write voltage pulse) is greater than or equal to a minimum voltage (here, 0.05 V) at which, when a voltage is applied between the first electrode 103 and the second electrode 105, a current starts flowing through the nonvolatile memory element 100 where the resistance state of the nonvolatile memory element 100 is the low resistance state, and less than or equal to a maximum voltage (here, 0.75 V) at which the progression of the resistance change to the low resistance state is not caused in the nonvolatile memory element 100 in the low resistance state when a voltage is applied between the first electrode 103 and the second electrode 105.

### Embodiment 2

An embodiment 2 is a 1 transistor/1 resistance (what is called, 1T1R) nonvolatile memory device which includes the nonvolatile memory element described in the embodiment 1.

[Configuration of Nonvolatile Memory Device]

FIG. 12 is a block diagram of a configuration example of a nonvolatile memory device according to the embodiment of the present invention. As shown in FIG. 12, the nonvolatile memory device 300 according to the present embodiment includes a memory cell array 301 including nonvolatile memory elements R311 to R322, an address buffer 302, a control unit 303, a row decoder 304, a word-line driver 305, a column decoder 306, and a bit-line/plate-line driver 307. The bit-line/plate-line driver 307 includes sense circuitry (sense amplifier) and can measure current flowing through bit lines or plate lines.

The memory cell array 301 includes two word lines W1 and W2 extending in parallel with each other, two bit lines B1 and B2 extending in parallel with each other crossing the word lines W1 and W2, two plate lines P1 and P2 provided with the bit lines B1 and B2 in one-to-one correspondence, respectively, and four memory cells MC311, MC312, MC321, and MC322 provided in matrix corresponding to cross points of the word lines W1 and W2 and the bit lines B1 and B2. The memory cells MC311, MC312, MC321, and MC322 include a selection transistor T311 and the nonvolatile memory element R311, a selection transistor T312 and the nonvolatile memory element R312, a selection transistor T321 and the nonvolatile memory element R321, and a selection transistor T322 and the nonvolatile memory element R322, respectively. Here, the nonvolatile memory elements R311 to R322 each correspond to the nonvolatile memory element 100 according to the embodiment 1.

It should be noted that the number of the components are not limited to the above. For example, the memory cells included in the memory cell array 301 is not limited to four memory cells as described above, and may be five or more memory cells.

It should be noted that while in the above configuration example, the plate lines are disposed in parallel with the bit lines, the plate lines may be disposed in parallel with the word lines. Moreover, while the plate lines are configured to provide a common potential to transistors connected thereto, the above configuration may include a source select circuit and a driver having the same configurations as the row decoder 304 and the word-line driver 305, respectively, and a selected source line and an unselected souse line may be driven by different voltages (including polarity).

Further describing the configuration of the memory cell array 301, the memory cell MC311 (the selection transistor T311 and the nonvolatile memory element R311) is provided between the bit line B1 and the plate line P1 in a manner that a source of the selection transistor T311 and the nonvolatile memory element R311 are connected in series. More specifically, the selection transistor T311 is connected to the bit line B1 and the nonvolatile memory element R311 between the bit line B1 and the nonvolatile memory element R311, and the nonvolatile memory element R311 is connected to the selection transistor T311 and the plate line P1 between the selection transistor T311 and the plate line P1. A gate of the selection transistor T311 is connected to the word line W1. It should be noted that the other memory cells MC312, MC321, and MC322 have the same configuration as the memory cell MC311, and thus the description will be omitted.

According to the above configuration, when a predetermined voltage (an activation voltage) is supplied to each of the gates of the selection transistors T311, T312, T321, and T322 via the word lines W1 and W2, conduction between the drain and the source of each of the selection transistors T311, T312, T321, and T322 is permitted.

The address buffer 302 receives an address signal ADDRESS from an external circuit (not shown), and based on the address signal ADDRESS, outputs a row address signal ROW to the row decoder 304 and outputs a column address signal COLUMN to the column decoder 306. Here, the address signal ADDRESS is a signal indicative of an address of a memory cell selected from among the memory cells MC311 to MC322. The row address signal ROW is a signal indicative of a row address and the column address signal COLUMN is an address indicative of a column address, in the address indicated by the address signal ADDRESS.

The address buffer 302, the row decoder 304, the word-line driver 305, the column decoder 306, and the bit-line/plate-line driver 307 form a selection circuit which selects, from the memory cell array 301, a memory cell (or the nonvolatile memory element) to/from which data is to be written/read.

The control unit 303 selects one of WRITE mode, ERASE mode, and READ mode, according to a mode selection signal MODE received from the external circuit, and provides controls corresponding to the selected mode. It should be noted that, herein, WRITE mode changes the resistance state of the nonvolatile memory element to the low resistance state, ERASE mode changes the resistance state of the nonvolatile memory element to the high resistance state, and READ mode reads out data from the nonvolatile memory element (determines the resistance state of the nonvolatile memory element). Hereinafter, for voltage application, it is assumed that each voltage is applied based on the plate line.

In WRITE mode, according to input data Din received from the external circuit, the control unit 303 outputs to the bit-line/plate-line driver 307 a control signal CONT instructing “application of the write voltage.” In WRITE mode, the control unit 303 also outputs to the bit-line/plate-line driver 307 a control signal CONT instructing “application of the first fluctuation determination voltage.”

In READ mode, the control unit 303 outputs to the bit-line/plate-line driver 307 a control signal CONT instructing “application of the read voltage.” In READ mode, the control unit 303 further receives an IREAD outputted from the bit-line/plate-line driver 307, and outputs output data Dout indicative of a bit value according to the signal IREAD to the external circuit output. The signal IREAD indicates a value of the current flowing through the plate lines P1 and P2 in READ mode.

In ERASE mode, the control unit 303 outputs to the bit-line/plate-line driver 307 a control signal CONT instructing “application of the erase voltage.” In ERASE mode, the control unit 303 also outputs to the bit-line/plate-line driver 307 a control signal CONT instructing “application of the second fluctuation determination voltage.”

In WRITE mode and ERASE mode also, the control unit 303 performs the same processing as in READ mode to perform the verify read process.

The row decoder 304 receives the row address signal ROW outputted from the address buffer 302, and selects either one of the two word lines W1 and W2, according to the row address signal ROW. The word-line driver 305 applies the activation voltage to the word line selected by the row decoder 304, based on an output signal from the row decoder 304.

The column decoder 306 receives the column address signal COLUMN outputted from the address buffer 302, and according to the column address signal COLUMN, selects one of the two bit lines B1 and B2, and one of the two plate lines P1 and P2 that corresponds to the selected bit line.

Once received the control signal CONT instructing “application of the write voltage” from the control unit 303, the bit-line/plate-line driver 307 applies a write voltage VWRITE (write voltage pulse) between the bit line and the plate line, which are selected by the column decoder 306, based on an output signal from the column decoder 306. Moreover, once received the control signal CONT instructing “application of the first fluctuation determination voltage” from the control unit 303, the bit-line/plate-line driver 307 applies a first fluctuation determination voltage VFLUC1 (a first fluctuation determination voltage pulse) between the same bit line and the same plate line.

Moreover, once received the control signal CONT instructing “application of the read voltage” from the control unit 303, the bit-line/plate-line driver 307 applies a read voltage VREAD (read voltage pulse) between the bit line and the plate line, which are selected by the column decoder 306, based on the output signal from the column decoder 306. Then, the bit-line/plate-line driver 307 outputs to the control unit 303 the signal IREAD indicative of the value of the current flowing through the plate line.

Furthermore, once received the control signal CONT instructing “application of the erase voltage” from the control unit 303, the bit-line/plate-line driver 307 applies an erase voltage VRESET (write voltage pulse) between the bit line and the plate line, which are selected by the column decoder 306, based on the output signal from the column decoder 306. Moreover, once received the control signal CONT instructing “application of the second fluctuation determination voltage” from the control unit 303, the bit-line/plate-line driver 307 applies a second fluctuation determination voltage VFLUC2 (a second fluctuation determination voltage pulse) between the same bit line and the same plate line.

Here, values of the write voltage VWRITE and the first fluctuation determination voltage VFLUC1 are set to, for example, −2.4 V and −0.7 V, respectively, and the pulse width in both cases is set to 100 ns. A value of the read voltage VREAD is set to, for example, +0.4 V. Values of the erase voltage VRESET and the second fluctuation determination voltage VFLUC2 are set to, for example, +2.0 V and +0.7 V, respectively, and the pulse width in both cases is set to 100 ns.

[Operation of Nonvolatile Memory Device]

Hereinafter, example operation of the nonvolatile memory device 300 configured as described above will be described separately in WRITE mode, READ mode, and ERASE mode described above.

It should be noted that, hereinafter, the case where the nonvolatile memory element is in the low resistance state corresponds to data “1,” and the case where the nonvolatile memory element is in the high resistance state corresponds to data “0.” Moreover, for purposes of description, it is assumed that the address signal ADDRESS is a signal indicative of the address of the memory cell MC311.

(WRITE Mode)

In WRITE mode, the control unit 303 performs S105 to S109 described in the embodiment 1 with reference to FIG. 7A. In particular, the control unit 303 outputs the control signals CONT instructing “application of the write voltage” and “application of the first fluctuation determination voltage” to the bit-line/plate-line driver 307 in the stated order. This performs “LR write process” (S105) and “Fluctuation determination writing process” (S106) on the memory cell MC311.

Next, the control unit 303 outputs the control signal CONT instructing “application of the read voltage” to the bit-line/plate-line driver 307, and thereafter determines whether the current value indicated by the signal IREAD received from the bit-line/plate-line driver 307 corresponds to the value of the current which flows when the nonvolatile memory element R311 is in the low resistance state. “Verify read process” (S107) is performed in such a manner. Then, based on a result of the verify read process, the control unit 303 determines if the low resistance state set by the previous LR writing has been lost, that is, the resistance value of the nonvolatile memory element R311 of the memory cell MC311 is likely to fluctuate (S108). As a result, when determined that the resistance value of the nonvolatile memory element R311 is likely to fluctuate, the control unit 303 outputs again the control signal CONT instructing “application of the write voltage” to the bit-line/plate-line driver 307. This performs “Rewrite process” (S109) on the memory cell MC311. On the other hand, when determined that the resistance value of the nonvolatile memory element R311 hardly fluctuates, the control unit 303 ends the processing on the memory cell MC311 without performing “Rewrite process” thereon.

(READ Mode)

In READ mode, the control unit 303 outputs the control signal CONT instructing “application of the read voltage” to the bit-line/plate-line driver 307. In response, the bit-line/plate-line driver 307 applies the read voltage VREAD (read voltage pulse) between the bit line B1 and the plate line P1, and thereafter outputs to the control unit 303 the signal IREAD indicative of the value of the current flowing through the plate line P1.

The control unit 303 determines the output data Dout corresponding to the current value indicated by the signal IREAD received from the bit-line/plate-line driver 307, and outputs the determined output data Dout to outside. In the present embodiment, if the current value indicated by IREAD corresponds to the value of the current which flows when the nonvolatile memory element R311 is in the low resistance state, the control unit 303 outputs the output data Dout indicative of “1.” On the other hand, if the current value indicated by IREAD corresponds to the value of the current which flows when the nonvolatile memory element R311 is in the high resistance state, the control unit 303 outputs the output data Dout indicative of “0.”

(ERASE Mode)

In ERASE mode, the control unit 303 performs steps S102 to S104, and S108 and S109 described in the embodiment 1 with reference to FIG. 7A. In particular, the control unit 303 outputs the control signals CONT instructing “application of the erase voltage” and “application of the second fluctuation determination voltage” to the bit-line/plate-line driver 307 in the stated order. This performs “HR write process” (S102) and “Fluctuation determination writing process” (S103) on the memory cell MC311.

Next, the control unit 303 outputs the control signal CONT instructing “application of the read voltage” to the bit-line/plate-line driver 307, and thereafter determines whether the current value indicated by the signal IREAD received from the bit-line/plate-line driver 307 corresponds to the value of the current which flows when the nonvolatile memory element R311 is in the high resistance state. “Verify read process” (S104) is performed in such a manner. Then, based on a result of the verify read process, the control unit 303 determines if the high resistance state set by the previous HR writing has been lost, that is, the resistance value of the nonvolatile memory element R311 of the memory cell MC311 is likely to fluctuate (S108). As a result, when determined that the resistance value of the nonvolatile memory element R311 is likely to fluctuate, the control unit 303 outputs again the control signal CONT instructing “application of the erase voltage” to the bit-line/plate-line driver 307. This performs “Rewrite process” (S109) on the memory cell MC311. On the other hand, when determined that the resistance value of the nonvolatile memory element R311 hardly fluctuate, the control unit 303 ends the processing on the memory cell MC311 without performing “Rewrite process” thereon.

In summary, the nonvolatile memory device 300 according to the present embodiment includes: as principal components, (1) the nonvolatile memory element R311 or the like which includes the first electrode 103, the second electrode 105, and the variable resistance layer 104 comprising a metal oxide and sandwiched between the first electrode 103 and the second electrode 105; as functional components, (2) a write unit which applies, between the first electrode 103 and the second electrode 105, the first voltage pulse (a write voltage pulse) for changing the resistance state of the nonvolatile memory element R311 or the like from the first state to the second state, and thereafter, applies, between the first electrode 103 and the second electrode 105, the second voltage pulse (the fluctuation determination voltage pulse) that has the same polarity as the first voltage pulse and a voltage value of which has a smaller absolute value than the first voltage pulse; (3) a determination unit which determines whether the resistance state of the nonvolatile memory element R311 or the like is in the second state after the application of the second voltage pulse; and (4) a rewrite unit which applies, between the first electrode 103 and the second electrode 105, the third voltage pulse (a write voltage pulse) for changing the resistance state of the nonvolatile memory element R311 or the like from the first state to the second state, when the determination unit determines that the resistance state of the nonvolatile memory element R311 or the like is not the second state.

Here, the write unit, the determination unit, and the rewrite unit are, as described above, implemented, mainly in the control unit 303 and the bit-line/plate-line driver 307.

According to such a configuration, in the present embodiment, for writing to the nonvolatile memory element R311 or the like, the normal writing is performed and then the fluctuation determination writing is performed, and if it is determined that the resistance value of the nonvolatile memory element R311 or the like is likely to fluctuate, the data rewriting is performed. Thus, the data retention characteristics improve.

### Embodiment 3

An embodiment 3 is a cross point nonvolatile memory device which includes the nonvolatile memory element described in the embodiment 1. Here, the cross point nonvolatile memory device is a memory device in which an active layer is interposed between a cross-point (three-dimensionally crossing point) of the word line and the bit line. Hereinafter, the configuration and operation of the nonvolatile memory device will be described.

[Configuration of Nonvolatile Memory Device]

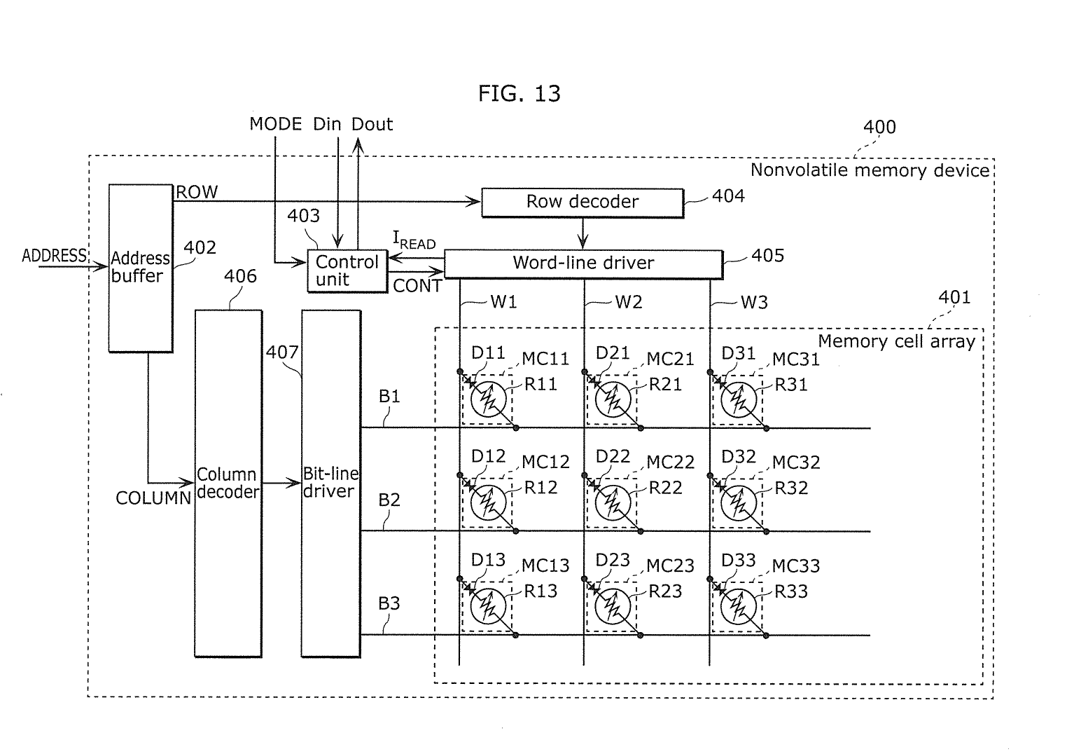

FIG. 13 is a block diagram of a configuration example of a nonvolatile memory device according to the embodiment of the present invention. As shown in FIG. 13, a nonvolatile memory device 400 according to the present embodiment includes a memory cell array 401 including nonvolatile memory elements R11 to R33, an address buffer 402, a control unit 403, a row decoder 404, a word-line driver 405, a column decoder 406, and a bit-line driver 407. The bit-line driver 407 includes a sense circuitry and can measure the current flowing through the bit lines.

The memory cell array 401 includes a plurality of word lines W1, W2, and W3 formed extending in parallel with one another, and bit lines B1, B1, and B3 formed extending in parallel with one another crossing the word lines W1, W2, and W3. Here, the word lines W1, W2, and W3 are formed in a first plane parallel with the main surface of a substrate (not shown), and the bit lines B1, B1, and B3 are formed in a second plane located above or below the first plane and substantially in parallel with the first plane. Thus, the word lines W1, W2, and W3 and the bit lines B1, B1, and B3 are three-dimensionally crossing each other. Corresponding to the three-dimensional crossing, a plurality of memory cells MC11, MC12, MC13, MC21, MC22, MC23, MC31, MC32, and MC33 (hereinafter, represented as “memory cells MC11, MC12, and so on”) are provided.

Memory cells MC11, MC12, and so on each include corresponding one of the nonvolatile memory elements R11, R12, R13, R21, R22, R23, R31, R32, and R33 and corresponding one of current control elements D11, D12, D13, D21, and D22, D23, D31, D32, D33 which include, for example, a bidirectional diode, connected in series. The nonvolatile memory elements R11 to R33 are each connected to corresponding one of the bit lines B1, B1, and B3, and the current control elements D11 to D33 are each connected to each nonvolatile memory element and corresponding one of the word lines W1, W2, and W3. Here, the nonvolatile memory elements R11 to R22 each correspond to the nonvolatile memory element 100 according to the embodiment 1. Examples of the current control elements D11 to D33 include MIM (Metal Insulator Metal) diodes, MSM (Metal Semiconductor Metal) diodes, and varistors.

It should be noted that, as with the embodiment 2, that the number of the components are not limited to the above.

The address buffer 402 receives the address signal ADDRESS from the external circuit (not shown), and based on the address signal ADDRESS, outputs the row address signal ROW to the row decoder 404 and outputs the column address signal COLUMN to the column decoder 406. Here, the address signal ADDRESS is a signal indicative of an address of a memory cell selected from among the memory cells MC11, MC12, and so on. The row address signal ROW is a signal indicative of a row address in the address indicated by the address signal ADDRESS and the column address signal COLUMN is a signal indicative of a column address in the address indicated by the address signal ADDRESS.

The address buffer 402, the row decoder 404, the word-line driver 405, the column decoder 406, and the bit-line driver 407 form a selection circuit which selects, from the memory cell array 401, a memory cell (or the nonvolatile memory element) to/from which data is to be written/read.

According to the mode selection signal MODE received from the external circuit, the control unit 403 selects one of WRITE mode, ERASE mode, and READ mode, and controls corresponding to the selected mode. Hereinafter, for voltage application, it is assumed that each voltage is applied based on the bit line.

In WRITE mode and ERASE mode, according to the input data Din received from the external circuit, the control unit 403 outputs the write voltage pulse and the first fluctuation determination voltage pulse, and an erase voltage pulse and the second fluctuation determination voltage pulse to the word-line driver 405.

In READ mode, the control unit 403 outputs the read voltage pulse to the word-line driver 405. In READ mode, the control unit 403 further detects the value of the current flowing between the bit line B2 and the word line W2, and outputs the output data Dout indicative of a bit value corresponding to the current value to the external circuit.

In WRITE mode and ERASE mode also, the control unit 303 performs the same processing as in READ mode to perform the verify read process.

The row decoder 404 receives the row address signal ROW outputted from the address buffer 402, and selects one of the word lines W1, W2, and W3, according to the row address signal ROW. The word-line driver 405 applies a predetermined voltage to the word line selected by the row decoder 404, based on an output signal from the row decoder 404.

The column decoder 406 receives the column address signal COLUMN outputted from the address buffer 402, and selects one of the bit lines B1, B2, and B3, according to the column address signal COLUMN.

The bit-line driver 407 grounds the bit line selected by the column decoder 406, based on an output signal from the column decoder 406.

While the present embodiment is a one-layered cross point nonvolatile memory device, the present embodiment may be a multi-layered cross point nonvolatile memory device by stacking memory cell arrays.

Moreover, the positional relationship between the nonvolatile memory element and the current control element may be transposed. In other words, the word lines may be connected to the nonvolatile memory elements, and the bit lines may be connected to the current control elements.

Furthermore, the bit lines and/or the word lines may be configured to double as electrodes in the nonvolatile memory element.

[Operation of Nonvolatile Memory Device]

Next, example operation of the nonvolatile memory device 400 configured as described above will be described separately in WRITE mode, ERASE mode, and READ mode. It should be noted that since well-known methods are available for selecting a bit line and a word line, and applying a voltage pulse, the detailed description thereof will be omitted.

Hereinafter, writing/reading the memory cell MC22 will be described by way of example. It should be noted that, in general, on-resistance of the current control element (diode) included in a memory cell is higher than on-resistance of a transistor, and thus a voltage applied to the memory cell in each mode is higher than the case where the transistor is included in the memory cell.

(WRITE Mode)

In WRITE mode, the control unit 403 performs S105 to S109 described in the embodiment 1 with reference to FIG. 7A. In particular, to write data representing “1” to the memory cell MC22, the bit-line driver 407 grounds the bit line B2, and the word-line driver 405 electrically connects the word line W2 and the control unit 403. Then, the control unit 403 applies the write voltage pulse to the word line W2, and further applies the first fluctuation determination voltage pulse to the word line W2. This performs “LR write process” (S105) and “Fluctuation determination writing process” (S106) on the memory cell MC22.

Next, the control unit 403 outputs the read voltage pulse to the word line W2 via the word-line driver 405, and thereafter detects the value of the current flowing between the bit line B2 and the word line W2 (a current value according to the resistance value of the nonvolatile memory element R22 of the memory cell MC22). Then, the control unit 403 determines whether the current value corresponds to the value of the current which flows when the nonvolatile memory element R22 is in the low resistance state. “Verify read process” (S107) is performed in such a manner. Then, based on a result of the verify read process, the control unit 403 determines if the low resistance state set by the previous LR writing has been lost, that is, the resistance value of the nonvolatile memory element R22 of the memory cell MC22 is likely to fluctuate (S108). As a result, when determined that the resistance value of the nonvolatile memory element R22 is likely to fluctuate, the control unit 403 outputs again the write voltage pulse to the word line W2. This performs “Rewrite process” (S109) on the memory cell MC22. On the other hand, when determined that the resistance value of the nonvolatile memory element R22 hardly fluctuates, the control unit 403 ends the processing on the memory cell MC22 without performing “Rewrite process” thereon.

(READ Mode)

To read data written to the memory cell MC22, the bit-line driver 407 grounds the bit line B2 and the word-line driver 405 electrically connects the word line W2 and the control unit 403. Then, the control unit 403 applies the read voltage pulse to the word line W2.

Once the read voltage pulse is applied to the memory cell MC22, a current having a value according to the resistance value of the nonvolatile memory element R22 of the memory cell MC22 flows between the bit line B2 and the word line W2. The control unit 403 detects the current value, and determines the resistance state of the nonvolatile memory element R22, based on the current value. Here, if the nonvolatile memory element R22 is in the low resistance state, it can be found that the data written to the memory cell MC22 is “1.” On the other hand, if the nonvolatile memory element R22 is in the high resistance state, it can be found that the data written to the memory cell MC22 is “0.”

(ERASE Mode)

In ERASE mode, the control unit 403 performs S102 to S104, S108 and S109 described in the embodiment 1 with reference to FIG. 7A. In particular, to write the data representing “0” to the memory cell MC22, the bit-line driver 407 grounds the bit line B2, and the word-line driver 405 electrically connects the word line W2 and the control unit 403. Then, the control unit 403 applies the erase voltage pulse to the word line W2, and further applies the second fluctuation determination voltage pulse to the word line W2. This performs “HR write process” (S102) and “Fluctuation determination writing process” (S103) on the memory cell MC22.

Next, the control unit 403 outputs the read voltage pulse to the word line W2 via the word-line driver 405, and thereafter, detects the value of the current flowing between the bit line B2 and the word line W2 (a current value according to the resistance value of the nonvolatile memory element R22 of the memory cell MC22). Then, the control unit 403 determines whether the current value corresponds to the value of the current which flows when the nonvolatile memory element R22 is in the high resistance state. “Verify read process” (S104) is performed in such a manner. Then, based on a result of the verify read process, the control unit 403 determines if the high resistance state set by the previous HR writing has been lost, that is, the resistance value of the nonvolatile memory element R22 of the memory cell MC22 is likely to fluctuate (S108). As a result, when determined that the resistance value of the nonvolatile memory element R22 is likely to fluctuate, the control unit 403 outputs again the erase voltage pulse to the word line W2. This performs “Rewrite process” (S109) on the memory cell MC22. On the other hand, when determined that the resistance value of the nonvolatile memory element R22 hardly fluctuates, the control unit 403 ends the processing on the memory cell MC22 without performing “Rewrite process” thereon.

In summary, the nonvolatile memory device 400 according to the present embodiment includes: as principal components, (1) the nonvolatile memory element R11 or the like which includes the first electrode 103, the second electrode 105, and the variable resistance layer 104 comprising a metal oxide and sandwiched between the first electrode 103 and the second electrode 105; as functional components, (2) the write unit which applies, between the first electrode 103 and the second electrode 105, the first voltage pulse (a write voltage pulse) for changing the resistance state of the nonvolatile memory element R11 or the like from the first state to the second state, and thereafter, applies, between the first electrode 103 and the second electrode 105, the second voltage pulse (the fluctuation determination voltage pulse) that has the same polarity as the first voltage pulse and a voltage value of which has a smaller absolute value than the first voltage pulse; (3) the determination unit which determines whether the resistance state of the nonvolatile memory element R11 or the like is in the second state after the application of the second voltage pulse; and (4) the rewrite unit which applies, between the first electrode 103 and the second electrode 105, the third voltage pulse (a write voltage pulse) for changing the resistance state of the nonvolatile memory element R11 or the like from the first state to the second state, when the determination unit determines that the resistance state of the nonvolatile memory element R11 or the like is not the second state.

Here, the write unit, the determination unit, and the rewrite unit are, as described above, implemented, mainly in the control unit 403 and the bit-line driver 407.

According to such a configuration, in the present embodiment, for writing to the nonvolatile memory element R11 or the like, the normal writing is performed and then the fluctuation determination writing is performed, and if it is determined that the resistance value of the nonvolatile memory element R11 or the like is likely to fluctuate, the data rewriting is performed. Thus, the data retention characteristics improve.

### Other Embodiment

In the above embodiments, the fluctuation determination voltage pulse writing is performed for both the HR writing and the LR writing. However, the fluctuation determination voltage pulse writing may be performed for one of them. In particular, since it is observed that the fluctuation phenomenon in resistance value is more significant in the high resistance state than the low resistance state, the fluctuation determination voltage pulse writing may be performed only for the HR writing.

Moreover, in the above embodiments, the description has been given, by way of example, that a voltage pulse in the same conditions as that in the normal write process (S102 or S105) is applied in the rewrite process (S109), the voltage pulse for the rewrite process is not limited thereto. For example, the voltage pulse for the rewrite process may be greater than the voltage pulse for the normal write process in absolute value. This assuredly performs the rewriting. On the other hand, if the voltage pulse for the rewrite process is the same as the voltage pulse for the normal write process as described above, the configuration of the nonvolatile memory device (for example, the rewrite unit) can be simplified.

### INDUSTRIAL APPLICABILITY

The data write method for writing data to the nonvolatile memory element and the nonvolatile memory device according to the present invention are useful as a data write method for writing data to a nonvolatile memory element and as a memory device, respectively, for use in various electronic devices such as personal computers and mobile phones.

### REFERENCE SIGNS LIST

100, 201, R11 to R33, R311 to R322 Nonvolatile memory element
101 Substrate
102 Interlayer insulating film
103 First electrode
104 Variable resistance layer
104a First metal oxide layer
104b Second metal oxide layer
105 Second electrode
202 Load resistance
203, 204 Terminal
300, 400 Nonvolatile memory device
301, 401 Memory cell array
302, 402 Address buffer
303, 403 Control unit
304, 404 Row decoder
305, 405 Word-line driver
306, 406 Column decoder
   307 Bit-line/plate-line driver
407 Bit-line driver
MC11 to MC33, MC311 to MC322 Memory cell
T311 to T322 Selection transistor
D11 to D33 Current control element

1-26. (canceled)

27. A data write method for writing data to a nonvolatile memory element including a first electrode, a second electrode, and a variable resistance layer comprising a metal oxide and interposed between the first electrode and the second electrode, the data write method comprising:
a first application step of applying, between the first electrode and the second electrode, a first voltage pulse for changing a resistance state of the nonvolatile memory element from a first state to a second state;
a second application step of applying, after the first application step, between the first electrode and the second electrode, a second voltage pulse which has a same polarity as the first voltage pulse and a voltage an absolute value of which is smaller than an absolute value of a voltage of the first voltage pulse;
a determination step of determining, after the second application step, whether the resistance state of the nonvolatile memory element is the second state; and
a third application step of applying, between the first electrode and the second electrode, a third voltage pulse for changing the resistance state of the nonvolatile memory element from the first state to the second state when it is determined in the determination step that the resistance state of the nonvolatile memory element is not the second state,
wherein the absolute value of the voltage of the second voltage pulse is greater than or equal to a minimum voltage at which a current starts flowing through the nonvolatile memory element upon application of a voltage between the first electrode and the second electrode when the resistance state of the nonvolatile memory element is the second state, and less than or equal to a maximum voltage at which breakdown is not caused in the nonvolatile memory element.

28. The data write method according to claim 27,
wherein the first state is a low resistance state, and the second state is a high resistance state in which a resistance value of the nonvolatile memory element is higher than the resistance value in the low resistance state.

29. The data write method according to claim 28,
wherein the minimum voltage is 0.6 V, and
the maximum voltage is 1.3 V.

30. The data write method according to claim 27,
wherein the first state is a high resistance state, and the second state is a low resistance state in which a resistance value of the nonvolatile memory element is lower than the resistance value in the high resistance state.

31. The data write method according to claim 30,
wherein the minimum voltage is 0.05 V, and
the maximum voltage is 0.75 V.

32. The data write method according to claim 27,
wherein the third voltage pulse has a same voltage as the first voltage pulse.

33. The data write method according to claim 27,
wherein the third voltage pulse has a voltage an absolute value of which is greater than the absolute value of the voltage of the first voltage pulse.

34. The data write method according to claim 27,
wherein the metal oxide is a tantalum oxide.

35. The data write method according to claim 27,
wherein the resistance state of the nonvolatile memory element transitions from the first state to the second state or from the second state to the first state, according to a polarity of a voltage pulse applied between the first electrode and the second electrode, the nonvolatile memory element being a bipolar memory element.

36. The data write method according to claim 27,
wherein the variable resistance layer has a stacked structure including a first metal oxide layer comprising a first metal oxide, and a second metal oxide layer comprising a second metal oxide, and
an oxygen deficiency in the first metal oxide layer is greater than an oxygen deficiency in the second metal oxide layer.

37. The data write method according to claim 36,
wherein the second metal oxide layer has a filament which is a current path through which a current having a locally high current density flows in the second metal oxide layer.

38. The data write method according to claim 36,
wherein the second metal oxide layer has a region having a locally high oxygen vacancy concentration in the second metal oxide layer.

39. A nonvolatile memory device comprising:
a nonvolatile memory element including a first electrode, a second electrode, and a variable resistance layer comprising a metal oxide and interposed between the first electrode and the second electrode;
a write unit configured to apply, between the first electrode and the second electrode, a first voltage pulse for changing a resistance state of the nonvolatile memory element from a first state to a second state, and subsequently, apply, between the first electrode and the second electrode, a second voltage pulse which has a same polarity as the first voltage pulse and a voltage an absolute value of which is smaller than an absolute value of a voltage of the first voltage pulse;
a determination unit configured to determine, after application of the second voltage pulse, whether the resistance state of the nonvolatile memory element is the second state; and
a rewrite unit configured to apply, between the first electrode and the second electrode, a third voltage pulse for changing the resistance state of the nonvolatile memory element from the first state to the second state when the determination unit determines that the resistance state of the nonvolatile memory element is not the second state,
wherein the absolute value of the voltage of the second voltage pulse is greater than or equal to a minimum voltage at which a current starts flowing through the nonvolatile memory element upon application of a voltage between the first electrode and the second electrode when the resistance state of the nonvolatile memory element is the second state, and less than or equal to a maximum voltage at which breakdown is not caused in the nonvolatile memory element.

40. The nonvolatile memory device according to claim 39,
wherein the first state is a low resistance state, and the second state is a high resistance state in which a resistance value of the nonvolatile memory element is higher than the resistance value in the low resistance state.

41. The nonvolatile memory device according to claim 40,
wherein the minimum voltage is 0.6 V, and
the maximum voltage is 1.3 V.

42. The nonvolatile memory device according to claim 39,
wherein the first state is a high resistance state, and the second state is a low resistance state in which a resistance value of the nonvolatile memory element is lower than the resistance value in the high resistance state.

43. The nonvolatile memory device according to claim 42,
wherein the minimum voltage is 0.05 V, and
the maximum voltage is 0.75 V.

44. The nonvolatile memory device according to claim 39,
wherein the metal oxide is a tantalum oxide.

45. The nonvolatile memory device according to claim 39,
wherein the resistance state of the nonvolatile memory element transitions from the first state to the second state or from the second state to the first state, according to a polarity of a voltage pulse applied between the first electrode and the second electrode, the nonvolatile memory element being a bipolar memory element.

46. The nonvolatile memory device according to claim 39,
wherein the variable resistance layer has a stacked structure including a first metal oxide layer comprising a first metal oxide, and a second metal oxide layer comprising a second metal oxide, and
an oxygen deficiency in the first metal oxide layer is greater than an oxygen deficiency in the second metal oxide layer.

47. The nonvolatile memory device according to claim 46,
wherein the second metal oxide layer has a filament which is a path through which a current having a locally high current density flows in the second metal oxide layer.

48. The nonvolatile memory device according to claim 46,
wherein the second metal oxide layer has a region having a locally high oxygen vacancy concentration in the second metal oxide layer.
